(19) United States
(12) Patent Application Publication
(10) Pub. No.: US 2025/0267871 A1
(43) Pub. Date: Aug. 21, 2025

(54) SEMICONDUCTOR MEMORY DEVICE, METHOD FOR MANUFACTURING THE SAME AND ELECTRONIC SYSTEM INCLUDING THE SAME

(71) Applicant: Samsung Electronics Co., Ltd., Suwon-si (KR)

(72) Inventors: Soochan Chung, Suwon-si (KR); Pyeongwoo Kim, Suwon-si (KR); Gilsung Lee, Suwon-si (KR); Wonseok Cho, Suwon-si (KR)

(21) Appl. No.: 18/889,474

(22) Filed: Sep. 19, 2024

(30) Foreign Application Priority Data
Feb. 15, 2024 (KR) 10-2024-0021676

(51) Int. Cl. H10B 43/40; G11C 16/04; H01L 25/065; H10B 43/10; H10B 43/27; H10B 43/35; H10B 80/00

(52) U.S. Cl. CPC H10B 43/40; G11C 16/0483; H01L 25/0652; H10B 43/10; H10B 43/27; H10B 43/35; H10B 80/00; H01L 2225/06506

(57) ABSTRACT

A semiconductor memory device comprises a peripheral circuit structure including a peripheral circuit substrate and a peripheral circuit element on the peripheral circuit substrate, a source layer including a first surface facing the peripheral circuit structure and a second surface opposite to the first surface, a stack structure including a plurality of mold insulating films and a plurality of gate electrodes alternately stacked on the first surface of the source layer, and a channel structure extending through the stack structure and contacting the source layer. The source layer is in contact with an uppermost gate electrode that is closest to the source layer among the plurality of gate electrodes.

### CROSS-REFERENCE TO RELATED APPLICATION

This application claims priority from Korean Patent Application No. 10-2024-0021676 filed on Feb. 15, 2024, in the Korean Intellectual Property Office, and all the benefits accruing therefrom under 35 U.S.C. 119, the contents of which in its entirety are herein incorporated by reference.

### FIELD

The present disclosure relates to a semiconductor memory device, a method for manufacturing the same, and an electronic system including the same. More specifically, the present disclosure relates to a semiconductor memory device including three-dimensionally arranged memory cells, a method for manufacturing the same, and an electronic system including the same.

### BACKGROUND

To meet increasing demand for semiconductor memory devices with high data storage capacity in electronic systems, schemes for increasing the data storage capacity of semiconductor memory devices are being researched. A semiconductor memory device including memory cells arranged in a three-dimensional manner (instead of memory cells arranged in a two-dimensional manner) has been proposed as one scheme for increasing the data storage capacity of semiconductor memory devices.

### SUMMARY

Some embodiments of the present disclosure provide a semiconductor memory device with improved performance and reliability.

Further embodiments of the present disclosure provide a method for manufacturing a semiconductor memory device with improved performance and reliability.

Still further embodiments of the present disclosure provide an electronic system including a semiconductor memory device with improved performance and reliability.

Other embodiments of the present disclosure are not limited to the above, and advantages according to the present disclosure that are not mentioned may be understood based on the following description, and may be more clearly understood with reference to the embodiments described herein.

According to an aspect of the present disclosure, there is provided a semiconductor memory device comprising a peripheral circuit structure including a peripheral circuit substrate and a peripheral circuit element on the peripheral circuit substrate, a source layer including a first surface facing the peripheral circuit structure and a second surface opposite to the first surface, a stack structure including a plurality of mold insulating films and a plurality of gate electrodes alternately stacked on the first surface of the source layer, and a channel structure extending through the stack structure and contacting the source layer, wherein the source layer is in contact with an uppermost gate electrode that is closest to the source layer among the plurality of gate electrodes.

According to another aspect of the present disclosure, there is provided a semiconductor memory device comprising a peripheral circuit structure including a peripheral circuit substrate and a peripheral circuit element on the peripheral circuit substrate, a memory cell structure stacked on the peripheral circuit structure and including a cell array area and an extension area adjacent the cell array area, wherein the memory cell structure includes an insulating film in the extension area and including a first surface facing the peripheral circuit structure and a second surface opposite to the first surface, a source layer in the cell array area and including a third surface facing the peripheral circuit structure and a fourth surface opposite to the third surface, a stack structure including a plurality of mold insulating films and a plurality of gate electrodes alternately stacked on the first surface and the third surface, and a channel structure including a semiconductor film extending in a vertical direction so as to intersect the plurality of gate electrodes, and a data storage film between the semiconductor film and the plurality of gate electrodes, wherein the semiconductor film protrudes beyond the stack structure and the data storage film and contacts the source layer, wherein an uppermost gate electrode that is closest to the source layer among the plurality of gate electrodes is in contact with the first surface and the third surface.

According to still another aspect of the present disclosure, there is provided an electronic system comprising a main substrate, a semiconductor memory device including a peripheral circuit structure and a memory cell structure sequentially stacked on the main substrate, and a controller on the main substrate and electrically connected to the semiconductor memory device, wherein the memory cell structure includes a source layer including a first surface facing the peripheral circuit structure and a second surface opposite to the first surface, a stack structure on the first surface of the source layer and including a plurality of gate electrodes sequentially stacked and spaced apart from each other, and a channel structure intersecting the plurality of gate electrodes and in contact with the source layer, wherein the source layer is in contact with an uppermost gate electrode that is closest to the source layer among the plurality of gate electrodes.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a schematic block diagram for illustrating a semiconductor memory device according to some embodiments.

FIG. 2 is a schematic circuit diagram for illustrating a semiconductor memory device according to some embodiments.

FIG. 3 and FIG. 4 are layout diagrams for illustrating a semiconductor memory device according to some embodiments.

FIG. 5 is a schematic cross-sectional view cut along A-A in FIG. 4.

FIGS. 6A, 6B, 6C, and 6D are various enlarged views of a R1 area in FIG. 5.

FIG. 7 is a schematic cross-sectional view for illustrating a semiconductor memory device according to some embodiments.

FIG. 8 is a schematic cross-sectional view for illustrating a semiconductor memory device according to some embodiments.

FIG. 9 illustrates various enlarged views of a R2 area in FIG. 8.

FIGS. 10, 11, 12, 13, 14, 15, 16, 17, 18, 19, 20, 21, and 22 are diagrams of intermediate structures corresponding to intermediate steps of a method for manufacturing a semiconductor memory device according to some embodiments.

FIGS. 23, 24, 25, 26, 27, and 28 are diagrams of intermediate structures corresponding to intermediate steps of a method for manufacturing a semiconductor memory device according to some embodiments.

FIG. 29 is a schematic block diagram for illustrating an electronic system according to some embodiments.

FIG. 30 is a schematic perspective view for illustrating an electronic system according to some embodiments.

FIG. 31 is a schematic cross-sectional view taken along I-I of FIG. 30.

### DETAILED DESCRIPTION OF EMBODIMENTS

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, contacting, or connected, no intervening components or layers are present.

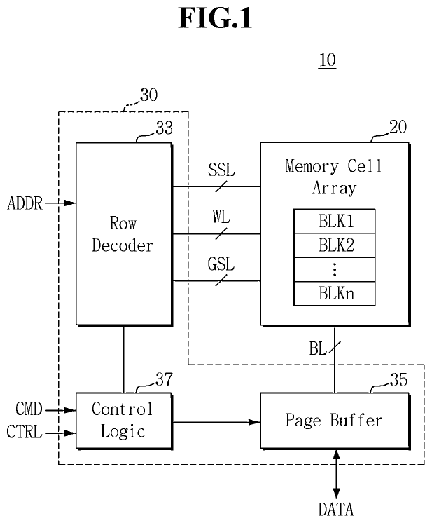

Hereinafter, referring to FIG. 1 to FIG. 9, a semiconductor memory device according to some embodiments is described.

FIG. 1 is an illustrative block diagram for illustrating a semiconductor memory device according to some embodiments.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 via a bit-line BL, a word-line WL, at least one string select line SSL, and at least one ground select line GSL. Specifically, the memory cell blocks BLK1 to BLKn may be connected to a row decoder 33 via the word-line WL, the string select line SSL and the ground select line GSL. Further, the memory cell blocks BLK1 to BLKn may be connected to a page buffer 35 via the bit-line BL.

The peripheral circuit 30 may receive an address ADDR, a command CMD, and a control signal CTRL from an external device to the semiconductor memory device 10, and may transmit and receive data to and from an external device to the semiconductor memory device 10. The peripheral circuit 30 may include a control logic 37, the row decoder 33, and the page buffer 35. Although not shown, the peripheral circuit 30 may further include various sub-circuits such as an input/output circuit, a voltage generation circuit for generating various voltages required for an operation of the semiconductor memory device 10, and an error correction circuit for correcting an error of the data read from the memory cell array 20.

The control logic 37 may be connected to the row decoder 33, the input/output circuit, and the voltage generation circuit. The control logic 37 may control overall operations of the semiconductor memory device 10. The control logic 37 may generate various internal control signals used in the semiconductor memory device 10 in response to the control signal CTRL. For example, the control logic 37 may adjust a voltage level of a voltage supplied to the word-line WL and the bit-line BL when performing a memory operation such as a program operation or an erase operation.

The row decoder 33 may select at least one of the plurality of memory cell blocks BLK1 to BLKn in response to the address ADDR, and may select at least one word-line WL, at least one string select line SSL, and at least one ground select line GSL of the selected at least one memory cell block BLK1 to BLKn. Further, the row decoder 33 may transmit a voltage for performing a memory operation to the word-line WL of the selected at least one memory cell block BLK1 to BLKn.

The page buffer 35 may be connected to the memory cell array 20 via the bit-line BL. The page buffer 35 may operate as a write driver or a sense amplifier. Specifically, when performing a program operation, the page buffer 35 operates as the write driver to apply a voltage based on the data to be stored in the memory cell array 20 to the bit-line BL. On the other hand, when performing a read operation, the page buffer 35 may operate as the sense amplifier to detect the data stored in the memory cell array 20.

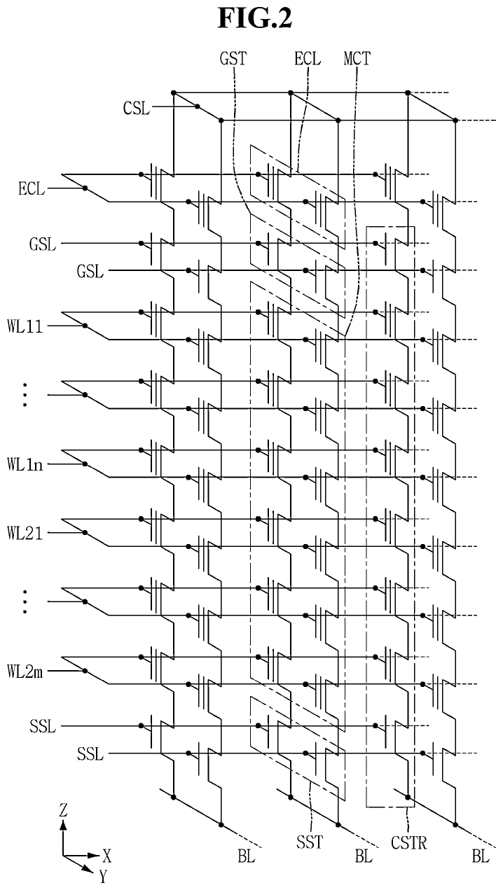

FIG. 2 is an illustrative circuit diagram for illustrating a semiconductor memory device according to some embodiments.

Referring to FIG. 2, the memory cell array (e.g., 20 in FIG. 1) of the semiconductor memory device according to some embodiments includes a common source line CSL, a plurality of bit-lines BL, and a plurality of cell strings CSTR.

The plurality of bit-lines BL may be two-dimensionally arranged in a plane defined by the first direction X and the second direction Y. For example, the bit-lines BL may be arranged and spaced apart from each other in the first direction X and extend in the second direction Y intersecting the first direction X. The plurality of cell strings CSTR may be connected in parallel to each of the bit-lines BL. The cell strings CSTR may be commonly connected to the common source line CSL. That is, the plurality of cell strings CSTR may be disposed between the bit-lines BL and the common source line CSL.

Each of the cell strings CSTR may include a ground select transistor GST connected to the common source line CSL, a string select transistor SST connected to the bit-line BL, and a plurality of memory cell transistors MCT disposed between the ground select transistor GST and the string select transistor SST. Each of the memory cell transistors MCT may include a data storage element. The ground select transistor GST, the string select transistor SST and the memory cell transistors MCT may be connected in series to each other in a vertical direction (hereinafter, a third direction Z). In accordance with the present disclosure, the third direction Z may intersect (for example, substantially perpendicular to) the first direction X and the second direction Y.

The common source line CSL may be commonly connected to sources of the ground select transistors GST. Further, a ground select line GSL, a plurality of word-lines WL11 to WL1n and WL21 to WL2m, and a string select line SSL may be disposed between the common source line CSL and the bit-line BL. The ground select line GSL may act as a gate electrode of the ground select transistor GST. The word-lines WL11 to WL1n and WL21 to WL2m may be respectively used as gate electrodes of the memory cell transistors MCT. The string select line SSL may act as a gate electrode of the string select transistor SST.

In some embodiments, an erase control transistor ECT may be disposed between the common source line CSL and the ground select transistor GST. The common source line CSL may be commonly connected to sources of the erase control transistors ECT. Further, an erase control line ECL may be disposed between the common source line CSL and the ground select line GSL. The erase control line ECL may act as a gate electrode of the erase control transistor ECT. The erase control transistors ECT may execute an erase operation of the memory cell array using gate induced drain leakage (GIDL).

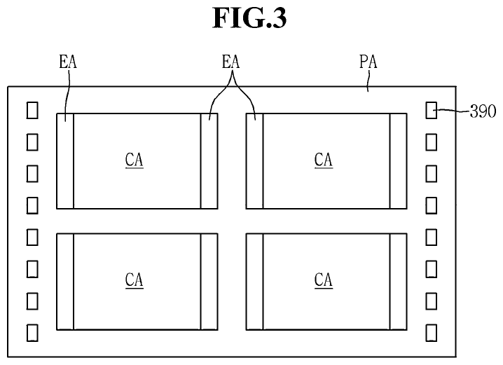

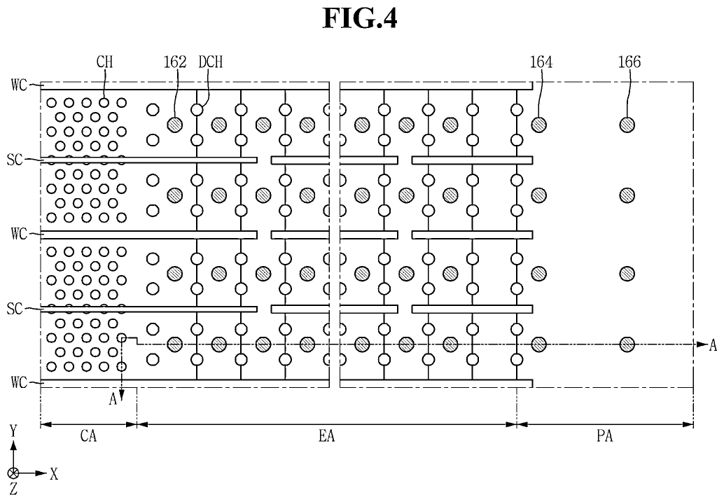

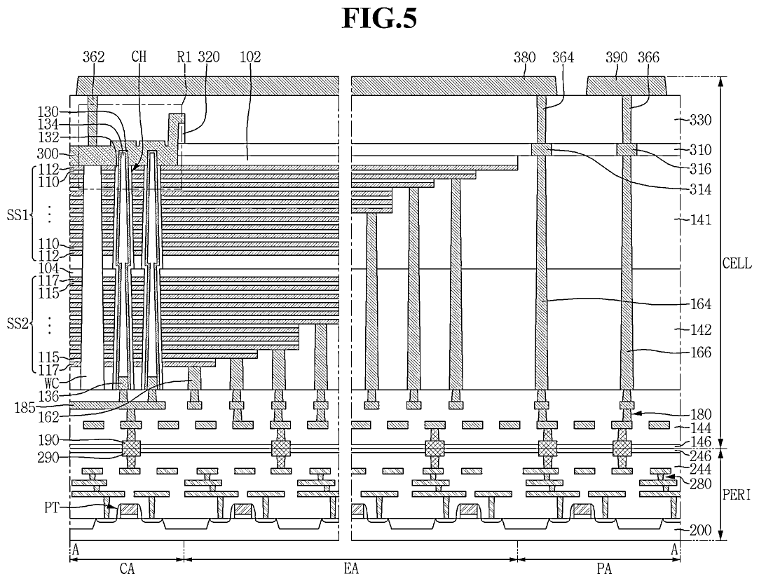

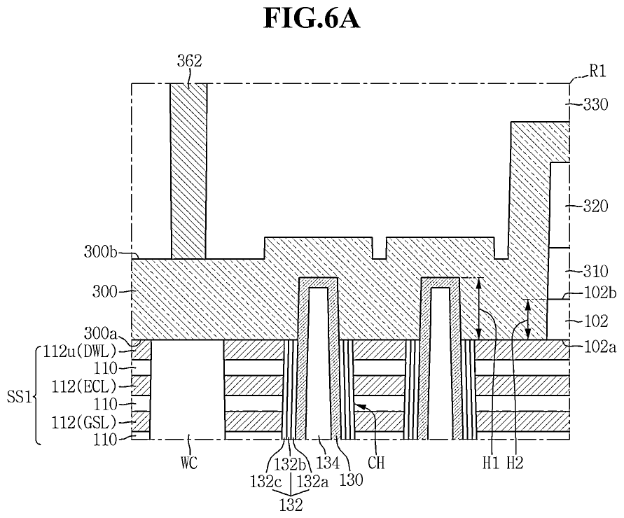

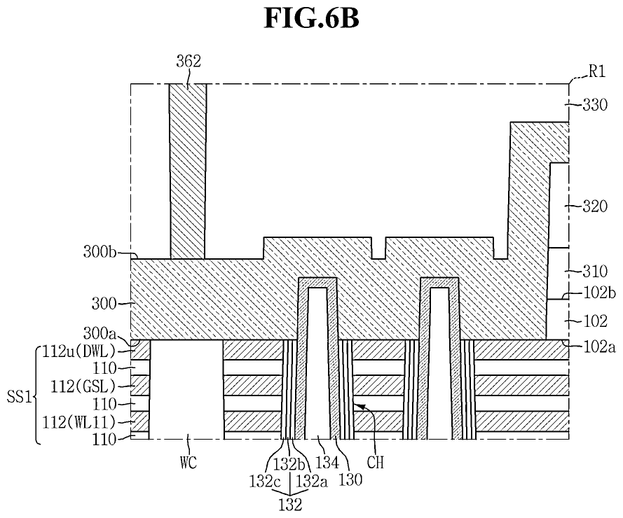

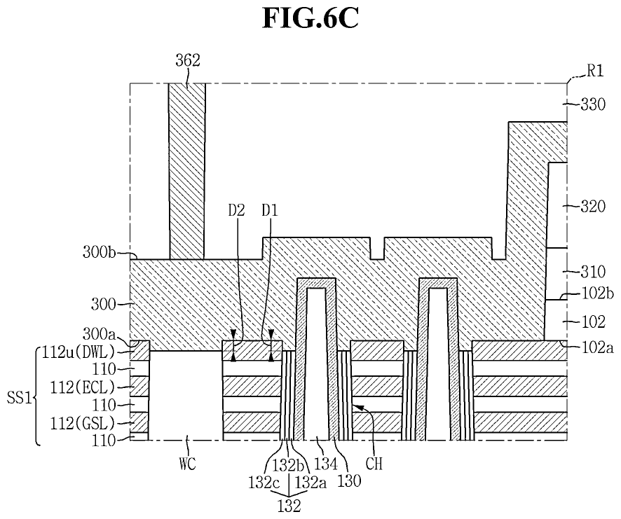

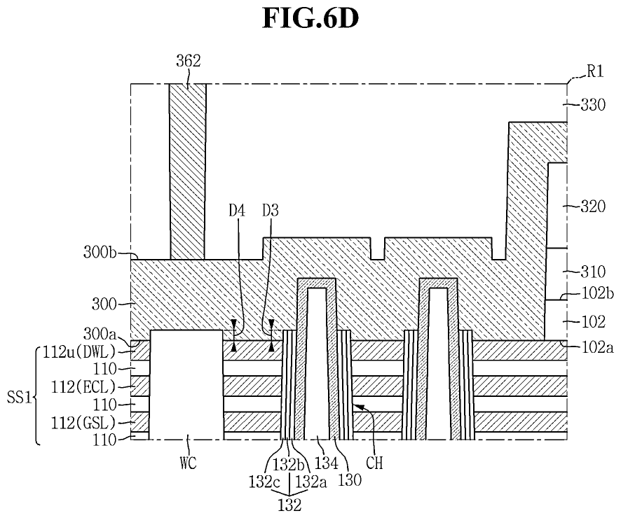

FIG. 3 and FIG. 4 are layout diagrams for illustrating a semiconductor memory device according to some embodiments. FIG. 5 is a cross-sectional view cut along A-A in FIG. 4. FIG. 6A to FIG. 6D are various enlarged views of a R1 area in FIG. 5.

Referring to FIG. 3 to FIG. 6A, a semiconductor memory device according to some embodiments includes a memory cell structure CELL and a peripheral circuit structure PERI.

The memory cell structure CELL may include a cell array area CA, an extension area EA, and a peripheral area PA.

A memory cell array (for example, 20 in FIG. 1) including a plurality of memory cells may be formed in the cell array area CA. For example, a channel structure CH, gate electrodes 112 and 117, a conductive line 185, and a source layer 300, which will be described later, may be disposed in the cell array area CA.

The extension area EA may be disposed around or adjacent the cell array area CA. For example, the extension area EA may be adjacent to the cell array area CA in the first direction X. In the extension area EA, the gate electrodes 112 and 117, which will be described later, may be stacked in a stepped manner.

The peripheral area PA may be a peripheral area surrounding the cell array area CA and the extension area EA. For example, the peripheral area PA may be adjacent to the cell array area CA and/or the extension area EA in the first direction X and/or the second direction Y. A conductive pad 390, which will be described later, may be disposed in the peripheral area PA.

The memory cell structure CELL may include a first base insulating film 102, a first stack structure SS1, a first interlayer insulating film 141, a second base insulating film 104, a second stack structure SS2, a second interlayer insulating film 142, a channel structure CH, a cutting pattern WC, a gate contact 162, a first through-via 164, a second through-via 166, a first wiring structure 180, a source layer 300, a pad insulating film 310, a first upper insulating film 320, a second upper insulating film 330, a connection pattern 380, and the conductive pad 390.

The first base insulating film 102 may provide an insulating area extending across the cell array area CA and the extension area EA. For example, the first base insulating film 102 may include at least one of silicon oxide, silicon nitride, and/or silicon oxynitride. However, embodiments of the present disclosure are not limited thereto. In one example, the first base insulating film 102 may include a silicon oxide film.

As shown in FIG. 6A, the first base insulating film 102 may include a first surface 102a and a second surface 102b which are opposite to each other. Each of the first surface 102a and the second surface 102b may extend along a horizontal plane (e.g., a XY plane). In following descriptions, the first surface 102a may also be referred to as a lower surface of the first base insulating film 102, and the second surface 102b may also be referred to as an upper surface of the first base insulating film 102.

The first stack structure SS1 may be formed on the lower surface of the first base insulating film 102. The first stack structure SS1 may include a plurality of first mold insulating films 110 and a plurality of first gate electrodes 112 that are alternately stacked on top of each other while being disposed on the lower surface of the first base insulating film 102. Each of the first mold insulating films 110 and each of the first gate electrodes 112 may have a layered structure extending along the horizontal plane (e.g., the XY plane). The first gate electrodes 112 may be sequentially stacked while adjacent ones thereof are spaced apart from each other via the first mold insulating film 110 disposed therebetween.

Each of the first gate electrodes 112 of the cell array area CA may extend further into the extension area EA. The first gate electrodes 112 of the extension area EA may be stacked in a stepwise manner on the first base insulating film 102, so as to define a stepped structure. For example, in the extension area EA, a length in the first direction X of each of the first gate electrodes 112 may be smaller as a spacing between each of the first gate electrodes 112 and the first base insulating film 102 increases.

In some embodiments, the first gate electrodes 112 may include at least one erase control line (e.g., ECL in FIG. 2), at least one ground select line (e.g., GSL in FIG. 2), and a plurality of first word-lines (e.g., WL11 to WL1n in FIG. 2) sequentially stacked on the lower surface of the first base insulating film 102. The number and shape of the first mold insulating films 110 and the first gate electrodes 112 are illustrative only and are not limited to those shown.

The first interlayer insulating film 141 may cover the first base insulating film 102 and the first stack structure SS1. The term “cover” or “surround” or “fill” as may be used herein may not require completely covering or surrounding or filling the described elements or layers, but may, for example, refer to partially covering or surrounding or filling the described elements or layers. The first interlayer insulating film 141 may include, but is not limited to, at least one of, for example, silicon oxide, silicon oxynitride, and/or a low-k material with a lower dielectric constant than that of silicon oxide.

The second base insulating film 104 may be formed on the lower surface of the first interlayer insulating film 141. The second base insulating film 104 may provide an insulating area extending across the cell array area CA and the extension area EA. For example, the second base insulating film 104 may include at least one of silicon oxide, silicon nitride, and/or silicon oxynitride. However, embodiments of the present disclosure are not limited thereto. In one example, the second base insulating film 104 may include a silicon oxide film.

The second stack structure SS2 may be formed on the lower surface of the second base insulating film 104. The second stack structure SS2 may include a plurality of second mold insulating films 115 and a plurality of second gate electrodes 117 that are alternately stacked on top of each other while being disposed on the lower surface of the second base insulating film 104. Each of the second mold insulating films 115 and each of the second gate electrodes 117 may have a layered structure extending along the horizontal plane (e.g., the XY plane). The second gate electrodes 117 may be sequentially stacked while adjacent ones thereof are spaced apart from each other via the second mold insulating film 115 disposed therebetween.

Each of the second gate electrodes 117 of the cell array area CA may extend further into the extension area EA. The second gate electrodes 117 of the extension area EA may be stacked in a stepwise manner to define a stepped gate structure on the second base insulating film 104. For example, in the extension area EA, a length in the first direction X of each of the second gate electrodes 117 may be smaller as a spacing between each of the second gate electrodes 117 and the second base insulating film 104 increases.

In some embodiments, the second gate electrodes 117 may include a plurality of second word-lines (e.g., WL21 to WL2m in FIG. 2) and at least one string select line (for example, SSL in FIG. 2) sequentially stacked on the lower surface of the second base insulating film 104. The number and shape of the second mold insulating films 115 and the second gate electrodes 117 are illustrative only and are not limited to those shown.

The second interlayer insulating film 142 may cover the second base insulating film 104 and the second stack structure SS2. The second interlayer insulating film 142 may include, but is not limited to, at least one of, for example, silicon oxide, silicon oxynitride, and/or a low-k material with a lower dielectric constant than that of silicon oxide.

Each of the gate electrodes 112 and 117 may include a conductive material, for example, a metal such as tungsten (W), molybdenum (Mo), ruthenium (Ru), cobalt (Co), or nickel (Ni), or a semiconductor material such as silicon. However, embodiments of the present disclosure are not limited thereto. In some embodiments, each of the gate electrodes 112 and 117 may include a metal film. In one example, each of the gate electrodes 112 and 117 may include at least one of a tungsten (W) film, a molybdenum (Mo) film, and/or a ruthenium (Ru) film.

Each of the mold insulating films 110 and 115 may include at least one of, for example, silicon oxide, silicon nitride, and/or silicon oxynitride. However, embodiments of the present disclosure are not limited thereto. In one example, each of the mold insulating films 110 and 115 may include a silicon oxide film.

Only two stack structures SS1 and SS2 are shown. However, this is just an example. The number of the stack structures SS1 and SS2 may be three or more.

The channel structure CH may be disposed within the cell array area CA. The channel structure CH may extend in the third direction Z and extend through the stack structures SS1 and SS2. This channel structure CH may intersect with the plurality of gate electrodes 112 and 117. For example, the channel structure CH may be a pillar-shaped (e.g., cylindrical) structure extending in the third direction Z.

In some embodiments, a plurality of channel structures CH may be arranged in a zigzag manner in plan view. For example, as shown in FIG. 4, the channel structures CH may be arranged in a staggered manner in each of the first direction X and the second direction Y. These channel structures CH may further improve an integration level of the semiconductor memory device. The number and the arrangement of the channel structures CH are illustrative only and are not limited to what are shown.

In some embodiments, each of the channel structure CH may have a stepped portion between the first stack structure SS1 and the second stack structure SS2. For example, as shown in FIG. 5, a side surface of each channel structure CH may have a bent portion at a boundary between the first interlayer insulating film 141 and the second base insulating film 104.

Each channel structure CH may include a semiconductor film 130 and a data storage film 132.

The semiconductor film 130 may extend in the third direction Z and intersect the plurality of gate electrodes 112 and 117. The semiconductor film 130 is shown as having a cup shape, but this is only an example. For example, the semiconductor film 130 may have various shapes, such as a cylindrical shape, a square column shape, or a solid pillar shape. The semiconductor film 130 may include, but is not limited to, a semiconductor material such as single crystal silicon, polycrystalline silicon, an organic semiconductor material, and carbon nanostructures.

The data storage film 132 may be interposed between the semiconductor film 130 and the plurality of gate electrodes 112 and 117. For example, the data storage film 132 may extend along an outer surface of the semiconductor film 130. The data storage film 132 may include, but is not limited to, at least one of silicon oxide, silicon nitride, silicon oxynitride, and a high dielectric constant material having a higher dielectric constant than that of silicon oxide. The high dielectric constant (high-k) material may include, for example, at least one of aluminum oxide, hafnium oxide, lanthanum oxide, tantalum oxide, titanium oxide, lanthanum hafnium oxide, lanthanum aluminum oxide, dysprosium scandium oxide, or combinations thereof.

In some embodiments, the data storage film 132 may be formed as a stack of multiple films. For example, as shown in FIG. 6A, the data storage film 132 may include a tunnel insulating film 132a, a charge storage film 132b, and a blocking insulating film 132c sequentially stacked on the outer surface of the semiconductor film 130.

The tunnel insulating film 132a may include, for example, silicon oxide or a high-k material having a higher dielectric constant than that of silicon oxide, such as aluminum oxide (Al₂O₃) or hafnium oxide (HfO₂). The charge storage film 132b may include, for example, silicon nitride. The blocking insulating film 132c may include, for example, silicon oxide or a high-k material having a higher dielectric constant than that of silicon oxide, such as aluminum oxide (Al₂O₃) or hafnium oxide (HfO₂).

In some embodiments, the semiconductor film 130 may protrude upwardly beyond the first stack structure SS1 and the data storage film 132. For example, one end (e.g., an upper end) of the semiconductor film 130 may be positioned at a higher level than that of each of an upper surface of the first stack structure SS1 and an upper surface of the data storage film 132. The term “level” may be used herein to denote a relative distance from a reference element, for example, the substrate 200.

In some embodiments, a vertical length or distance by which the semiconductor film 130 protrudes may be greater than a thickness of the first base insulating film 102. For example, as shown in FIG. 6A, a vertical length H1 from an upper surface of the first stack structure SS1 to an upper surface of the semiconductor film 130 may be greater than a vertical length H2 from the upper surface of the first stack structure SS1 to the upper surface (the second surface 102b) of the first base insulating film 102.

In some embodiments, the channel structure CH may further include a filling insulating film 134. The filling insulating film 134 may be formed to fill an inner space defined by the cup-shaped semiconductor film 130. The filling insulating film 134 may include, but is not limited to, an insulating material, for example, silicon oxide.

In some embodiments, the channel structure CH may further include a channel pad 136. The channel pad 136 may be formed to contact the other end (e.g., a bottom) of the semiconductor film 130. The channel pad 136 may include, but is not limited to, a conductive material, for example, polysilicon doped with impurities, metal, or metal silicide.

In some embodiments, a dummy channel structure DCH may be formed within the extension area EA. The dummy channel structure DCH may extend in the third direction Z and extend through at least a portion of the stack structures SS1 and SS2.

The dummy channel structure DCH may be formed at the same level as that of the channel structure CH, or may be formed at a different level from that of the channel structure CH. In one example, when the dummy channel structure DCH is formed at the same level as that of the channel structure CH, the dummy channel structure DCH may include the semiconductor film 130, the data storage film 132, the filling insulating film 134, and the channel pad 136 as described above. In another example, when the dummy channel structure DCH is formed at a different level from a level of the channel structure CH, the dummy channel structure DCH may be filled with an insulating material and/or a conductive material. A size (e.g., a width) of the dummy channel structure DCH may be equal to a size of the channel structure CH or may be different from the size of the channel structure CH. In some embodiments, the size of the dummy channel structure DCH may be larger than the size of the channel structure CH.

The cutting pattern WC may extend across the cell array area CA and the extension area EA. The cutting pattern WC extends in an elongate manner in the first direction X and may cut (e.g., extend completely through) the stack structures SS1 and SS2. Furthermore, each of a plurality of cutting patterns WC may extend in the first direction X and the plurality of cutting patterns WC may be spaced apart from each other and arranged along the second direction Y. The stack structures SS1 and SS2 may be cut by the plurality of cutting patterns WC into a plurality of memory cell blocks (e.g., BLK1 to BLKn in FIG. 1). For example, two adjacent cutting patterns WC may define one memory cell block therebetween. A plurality of channel structures CH may be disposed within each memory cell block defined by the cutting patterns WC.

In some embodiments, the cutting pattern WC may include an insulating material, for example, at least one of silicon oxide, silicon nitride, and/or silicon oxynitride. However, embodiments of the present disclosure are not limited thereto. In one example, the cutting pattern WC may include a silicon oxide film.

In some embodiments, an isolation pattern SC may be formed within the second stack structure SS2. The isolation pattern SC may extend in the first direction to cut the string select line (SSL in FIG. 2; for example, the lowest gate electrode among the second gate electrodes 117) of the second stack structure SS1. Each memory cell block defined by the cutting patterns WC may be divided by the isolation pattern SC into a plurality of string areas. In one example, the isolation pattern SC may define two string areas within one memory cell block. The isolation pattern SC may include an insulating material, for example, at least one of silicon oxide, silicon nitride, and/or silicon oxynitride. However, embodiments of the present disclosure are not limited thereto.

The gate contact 162 may be disposed within the extension area EA. A plurality of gate contacts 162 may be electrically connected to a corresponding plurality of gate electrodes 112 and 117, respectively. For example, each of the gate contacts 162 may extend in the third direction Z and extend through the first interlayer insulating film 141 and/or the second interlayer insulating film 142, and contact a corresponding one of the gate electrodes 112 and 117. In some embodiments, a width of the gate contact 162 may decrease as the gate contact extends toward the gate electrodes 112 and 117.

Each of the first through-via 164 and the second through-via 166 may be disposed within the peripheral area PA. Each of the first through-via 164 and the second through-via 166 may extend in the third direction Z and extend through the first interlayer insulating film 141 and the second interlayer insulating film 142. In some embodiments, each of a width of the first through-via 164 and a width of the second through-via 166 may decrease as each of the first through-via 164 and the second through-via 166 extends toward the pad insulating film 310.

The first wiring structure 180 may be formed on the second interlayer insulating film 142. The first wiring structure 180 may be electrically connected to the channel structure CH, the gate contact 162, the first through-via 164, and/or the second through-via 166. For example, the first inter-wiring insulating film 144 may be formed on the second interlayer insulating film 142. The first wiring structure 180 may be formed within the first inter-wiring insulating film 144 and connected to the channel structure CH, the gate contact 162, the first through-via 164, and/or the second through-via 166. The number of layers and arrangement of the first wiring structure 180 are illustrative only and are not limited to what are shown.

The first wiring structure 180 may include a conductive material, for example, at least one of aluminum (Al), copper (Cu), tungsten (W), molybdenum (Mo), cobalt (Co), ruthenium (Ru) and alloys thereof. However, the present disclosure is not limited thereto. In one example, the first wiring structure 180 may include a copper (Cu) wiring.

In some embodiments, the first wiring structure 180 may include a conductive line 185 disposed within the cell array area CA. The conductive line 185 may extend in an elongate manner in the second direction Y. Furthermore, each of a plurality of conductive lines 185 may extend in the second direction Y while the plurality of conductive lines 185 may be arranged along the first direction X while being spaced apart from each other.

The conductive line 185 may be electrically connected to the plurality of channel structures CH arranged along the second direction Y. For example, the conductive line 185 may be in contact with the other end (e.g., the bottom) of the semiconductor film 130 via the channel pad 136 of the channel structure CH. This conductive line 185 may act as a bit-line (e.g., BL in FIG. 2) of the semiconductor memory device according to some embodiments.

The source layer 300 may be formed on an upper surface of the first stack structure SS1. The source layer 300 of the cell array area CA may be electrically connected to the plurality of channel structures CH. For example, one end (e.g., the upper end) of the semiconductor film 130 protruding upwardly beyond the first stack structure SS1 and the data storage film 132 may be in contact with the source layer 300.

The source layer 300 may include a conductive material, for example, polysilicon doped with impurities, metal, or metal silicide. However, embodiments of the present disclosure are not limited thereto. In one example, the source layer 300 may include poly-silicon (poly-Si) doped with N-type impurities (e.g., phosphorus (P) or arsenic (As)). This source layer 300 may act as the common source line (e.g., CSL in FIG. 2) of the semiconductor memory device according to some embodiments.

The source layer 300 of the cell array area CA may contact a first gate electrode 112 (hereinafter, the uppermost gate electrode 112u) closest to the source layer 300 among a plurality of first gate electrodes 112. For example, the source layer 300 may extend through the first base insulating film 102 of the cell array area CA so as to contact an upper surface of the uppermost gate electrode 112u.

As shown in FIG. 6A, the source layer 300 may include a third surface 300a and a fourth surface 300b that are opposite to each other. Each of the third surface 300a and the fourth surface 300b may extend along the horizontal plane (e.g., XY plane). In following descriptions, the third surface 300a may also be referred to as a lower surface of the source layer 300, and the fourth surface 300b may also be referred to as an upper surface of the source layer 300.

In some embodiments, the third surface 300a of the source layer 300 may be coplanar with the first surface 102a of the first base insulating film 102. The stack structures SS1 and SS2 may be sequentially stacked on the first surface 102a and the third surface 300a. The uppermost gate electrode 112u of the cell array area CA may contact the third surface 300a of the source layer 300, and the uppermost gate electrode 112u of the extension area EA may contact the first surface 102a of the first base insulating film 102.

The uppermost gate electrode 112u may be electrically connected to the source layer 300. This uppermost gate electrode 112u may be used to reduce electrical resistance of the common source line (e.g., CSL in FIG. 2) including the source layer 300.

In some embodiments, the uppermost gate electrode 112u may be a dummy line DWL that does not receive gate voltage. In other words, the uppermost gate electrode 112u may be non-functional for performing memory read/write/erase operations as described herein. That is, unlike the erase control lines (e.g., ECL in FIG. 2), the ground select lines (e.g., GSL in FIG. 2), the word-lines (e.g., WL11 to 1n and WL21 to 2m in FIG. 2), and the string select lines (e.g., SSL in FIG. 2), the uppermost gate electrode 112u may not receive the gate voltage from the row decoder (e.g., 33 in FIG. 1). For example, the gate contact 162 may not be in contact with the uppermost gate electrode 112u of the dummy line DWL.

In some embodiments, the first gate electrode 112 closest to the uppermost gate electrode 112u among the plurality of first gate electrodes 112 may be the erase control line ECL. For example, as shown in FIG. 6A, the dummy line DWL, the erase control line ECL, and the ground select line GSL may be sequentially stacked on the third surface 300a of the source layer 300.

In some embodiments, unlike what is shown, at least one additional dummy line may be interposed between the dummy line DWL and the erase control line ECL and/or between the erase control line ECL and the ground select line GSL. That is, the first stack structure SS1 may include one or more dummy lines DWL.

In some embodiments, the source layer 300 may extend generally conformally along a profile of the upper surface of the uppermost gate electrode 112u and a side surface and an upper surface of the protruding portion of the semiconductor film 130.

In some embodiments, an upper surface of the data storage film 132 may be coplanar with an upper surface of the uppermost gate electrode 112u.

In some embodiments, an upper surface of the cutting pattern WC may be coplanar with the upper surface of the uppermost gate electrode 112u.

The pad insulating film 310 may be formed on the upper surface of the first base insulating film 102. The pad insulating film 310 may provide an insulating area extending across the extension area EA and the peripheral area PA. The pad insulating film 310 may include, but is not limited to, at least one of, for example, silicon oxide, silicon oxynitride, and/or a low-k material with a lower dielectric constant than that of silicon oxide.

The first upper insulating film 320 may be formed on an upper surface of the pad insulating film 310. The first upper insulating film 320 may include, but is not limited to, at least one of, for example, silicon oxide, silicon oxynitride, and/or a low-k material with a lower dielectric constant than that of silicon oxide.

In some embodiments, the source layer 300 may extend further along the first upper insulating film 320. For example, the source layer 300 may extend generally conformally along a side surface of the first base insulating film 102, a side surface of the pad insulating film 310, and a side surface and an upper surface of the first upper insulating film 320. A portion of the first base insulating film 102, a portion of the pad insulating film 310, and the first upper insulating film 320 may be interposed between the source layer 300 and the first stack structure SS1.

In some embodiments, a side surface of the source layer 300 and a side surface of the first upper insulating film 320 may extend continuously.

The second upper insulating film 330 may cover the source layer 300, the pad insulating film 310, and the first upper insulating film 320. The second upper insulating film 330 may include, but is not limited to, at least one of, for example, silicon oxide, silicon oxynitride, and/or a low-k material with a lower dielectric constant than that of silicon oxide.

The connection pattern 380 may be formed on an upper surface of the second upper insulating film 330. The connection pattern 380 may electrically connect the first through-via 164 and the source layer 300 to each other. For example, a first contact pad 314 in contact with the first through-via 164 may be formed within the pad insulating film 310. Furthermore, a first contact pattern 362 extending throughs the second upper insulating film 330 so as to connect the source layer 300 and the connection pattern 380 to each other may be formed. A second contact pattern 364 extending through the second upper insulating film 330 so as to connect the first contact pad 314 to the connection pattern 380 may be formed.

The conductive pad 390 may be formed on the upper surface of the second upper insulating film 330. The conductive pad 390 may be electrically connected to the second through-via 166. For example, a second contact pad 316 in contact with the second through-via 166 may be formed within the pad insulating film 310. Furthermore, a third contact pattern 366 extending through the second upper insulating film 330 so as to connect the second contact pad 316 and the conductive pad 390 to each other may be formed.

The peripheral circuit structure PERI may include a peripheral circuit substrate 200, a peripheral circuit element PT, and a second wiring structure 280.

The peripheral circuit substrate 200 may include, for example, a semiconductor substrate such as a silicon substrate, a germanium substrate, or a silicon-germanium substrate. Alternatively, the peripheral circuit substrate 200 may include a silicon-on-insulator (SOI) substrate or a germanium-on-insulator (GOI) substrate etc.

The peripheral circuit element PT may be formed on the peripheral circuit substrate 200. The peripheral circuit element PT may provide a peripheral circuit (e.g., 30 in FIG. 1) that controls an operation of the semiconductor memory device. For example, the peripheral circuit element PT may include a control logic (e.g., 37 in FIG. 1), a row decoder (e.g., 33 in FIG. 1), and a page buffer (e.g., 35 in FIG. 1). In following description, a surface of the peripheral circuit substrate 200 on which the peripheral circuit element PT is disposed may be referred to as a front face (front side) of the peripheral circuit substrate 200. Conversely, a surface of the peripheral circuit substrate 200 opposite to the front face of the peripheral circuit substrate 200 may be referred to as a rear face (back side) of the peripheral circuit substrate 200.

The peripheral circuit element PT may include, for example, a transistor. However, the present disclosure is not limited thereto. For example, the peripheral circuit element PT may include not only various active elements such as transistors, but also various passive elements such as capacitors, resistors, and inductors.

The second wiring structure 280 may be formed on the peripheral circuit element PT. For example, a second inter-wiring insulating film 244 may be formed on the front face of the peripheral circuit substrate 200. The second wiring structure 280 may be formed within the second inter-wiring insulating film 244. The second wiring structure 280 may be electrically connected to the peripheral circuit element PT. The number of layers and the arrangement of the second wiring structure 280 as illustrated are only examples. The present disclosure is not limited thereto.

In some embodiments, the memory cell structure CELL may be stacked on the peripheral circuit structure PERI. For example, the memory cell structure CELL may be stacked on an upper surface of the second inter-wiring insulating film 244.

In some embodiments, the first surface 102a of the first base insulating film 102 and the third surface 300a of the source layer 300 may face the peripheral circuit structure PERI. For example, the stack structures SS1 and SS2 may be interposed between the source layer 300 and the peripheral circuit structure PERI and/or between the first base insulating film 102 and the peripheral circuit structure PERI.

The semiconductor memory device according to some embodiments may have a C2C (chip to chip) structure. The C2C structure may be manufactured by forming an upper chip including the memory cell structure CELL on a first wafer, and then forming a lower chip including the peripheral circuit structure PERI on a second wafer different from the first wafer, and then connecting the upper chip and the lower chip to each other in a bonding scheme.

In one example, the bonding scheme may refer to a scheme in which a first bonding metal 190 (and/or a first bonding insulating film 146) as the uppermost metal layer of the upper chip and a second bonding metal 290 (and/or a second bonding insulating film 246) as the uppermost metal layer of the lower chip are electrically connected to each other. For example, when each of the first bonding metal 190 and the second bonding metal 290 are made of copper (Cu), the bonding scheme may be a Cu—Cu bonding scheme. However, this is only an example. In another example, each of the first bonding metal 190 and the second bonding metal 290 may be made of various other metals such as aluminum (Al) or tungsten (W).

As the first bonding metal 190 and the second bonding metal 290 are bonded to each other, the first wiring structure 180 may be electrically connected to the second wiring structure 280. Thus, a plurality of memory cells formed in the cell array area CA may be electrically connected to the peripheral circuit element PT.

Referring to FIG. 5 and FIG. 6B, in the semiconductor memory device according to some embodiments, the first gate electrode 112 closest to the uppermost gate electrode 112u among the plurality of first gate electrodes 112 may be the ground select line GSL.

For example, as shown in FIG. 6B, the dummy line DWL, the ground select line GSL, and the first word-line WL11 may be sequentially stacked on the third surface 300a of the source layer 300.

In some embodiments, unlike what is shown, at least one additional dummy line may be interposed between the dummy line DWL and the ground select line GSL and/or between the ground select line GSL and the first word-line WL11.

Referring to FIG. 5 and FIG. 6C, in the semiconductor memory device according to some embodiments, the uppermost surface of the data storage film 132 is formed at a lower level than a level of the upper surface of the uppermost gate electrode 112u, relative to the substrate 200.

For example, the data storage film 132 may be recessed such that a vertical level of the uppermost surface of the data storage film 132 is lower than a vertical level of the upper surface of the uppermost gate electrode 112u. This data storage film 132 may not cover (i.e., may expose) at least a portion of a side surface of the uppermost gate electrode 112u. In other words, at least a portion of a side surface of the uppermost gate electrode 112u may be free of the data storage film 132. A portion of the source layer 300 may protrude toward the recessed data storage film 132 and may contact the portion of the side surface of the uppermost gate electrode 112u that is not covered with (i.e., is exposed by) the data storage film 132. The term “exposed” may describe relationships between elements within a device, but may not require exposure of the elements outside of the device.

It is shown that a vertical level of the uppermost surface of the data storage film 132 is higher than that of a lower surface of the uppermost gate electrode 112u, relative to the substrate 200. However, this is only an example. The vertical level of the uppermost surface of the data storage film 132 may be equal to or lower than the vertical level of the lower surface of the uppermost gate electrode 112u in some embodiments.

In some embodiments, the vertical level of the uppermost surface of the data storage film 132 may be higher than a vertical level of an upper surface of the first gate electrode 112 (for example, the erase control line ECL or the ground select line GSL) adjacent to the dummy line DWL. That is, the source layer 300 may not contact the erase control line ECL and/or the ground select line GSL.

In some embodiments, a vertical level of the uppermost surface of the cutting pattern WC may be lower than the vertical level of the uppermost surface of the uppermost gate electrode 112u, relative to the substrate 200. For example, the cutting pattern WC may be recessed such that the vertical level of the uppermost surface of the cutting pattern WC may be lower than that of the upper surface of the uppermost gate electrode 112u. This cutting pattern WC may not cover (i.e., may expose) at least a portion of a side surface of the uppermost gate electrode 112u. A portion of the source layer 300 may protrude toward the recessed cutting pattern WC and may contact the portion of the side surface of the uppermost gate electrode 112u that is not covered with or exposed by the cutting pattern WC.

It is shown that a depth D1 by which the data storage film 132 is recessed based on the upper surface of the uppermost gate electrode 112u and a depth D2 by which the cutting pattern WC is recessed based on the upper surface of the uppermost gate electrode 112u are equal to each other. However, this is only an example. In another example, the depth D1 by which the data storage film 132 is recessed may be greater than the depth D2 by which the cutting pattern WC is recessed, or may be smaller than the depth D2 by which the cutting pattern WC is recessed.

Referring to FIG. 5 and FIG. 6D, in the semiconductor memory device according to some embodiments, the vertical level of the uppermost surface of the data storage film 132 is higher than the vertical level of the upper surface of the uppermost gate electrode 112u, relative to the substrate 200.

For example, the uppermost surface of the data storage film 132 may protrude upwardly beyond the upper surface of the uppermost gate electrode 112u.

In some embodiments, the vertical level of the uppermost surface of the cutting pattern WC may be higher than the vertical level of the uppermost surface of the uppermost gate electrode 112u. For example, the uppermost surface of the cutting pattern WC may protrude upwardly beyond the upper surface of the uppermost gate electrode 112u.

A protruding vertical length D3 of the data storage film 132 based on the upper surface of the uppermost gate electrode 112u, and a protruding vertical length D4 of the cutting pattern WC based on the upper surface of the uppermost gate electrode 112u are shown to be equal to each other. However, this is only an example. In another example, the protruding vertical length D3 of the data storage film 132 may be greater than the protruding vertical length D4 of the cutting pattern WC, or may be smaller than the protruding vertical length D4 of the cutting pattern WC.

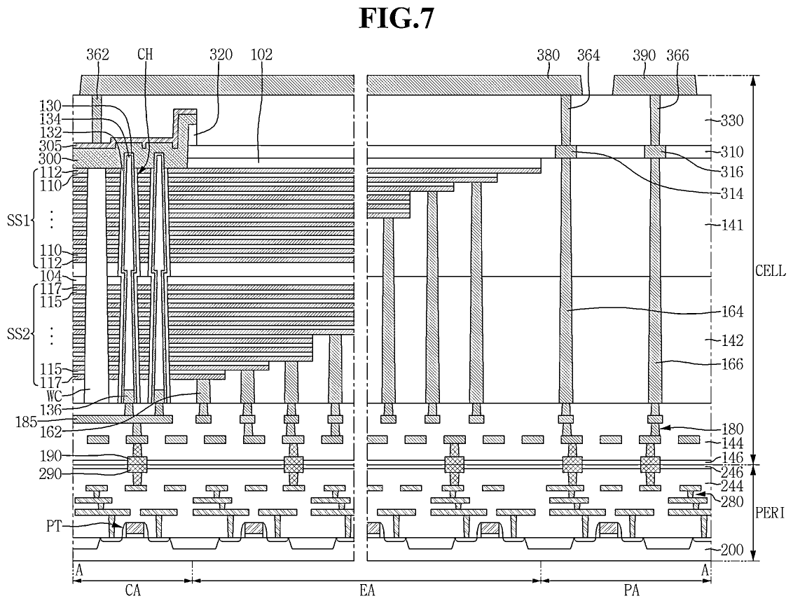

FIG. 7 is a cross-sectional view for illustrating a semiconductor memory device according to some embodiments. For convenience of description, descriptions similar or identical to those as set forth above using FIGS. 1 to 6D are briefly set forth or omitted.

Referring to FIG. 7, in a semiconductor memory device according to some embodiments, the memory cell structure CELL further includes a conductive plate 305.

The conductive plate 305 may be formed on the upper surface of the source layer 300. For example, the conductive plate 305 may extend generally conformally along the upper surface of the source layer 300. The conductive plate 305 may be electrically connected to the source layer 300. The conductive plate 305 may include a conductive material, for example, a metal such as tungsten (W), cobalt (Co), nickel (Ni), or a metal silicide. However, embodiments of the present disclosure are not limited thereto. This conductive plate 305 may be used to reduce the electrical resistance of the common source line (e.g., CSL in FIG. 2) including the source layer 300.

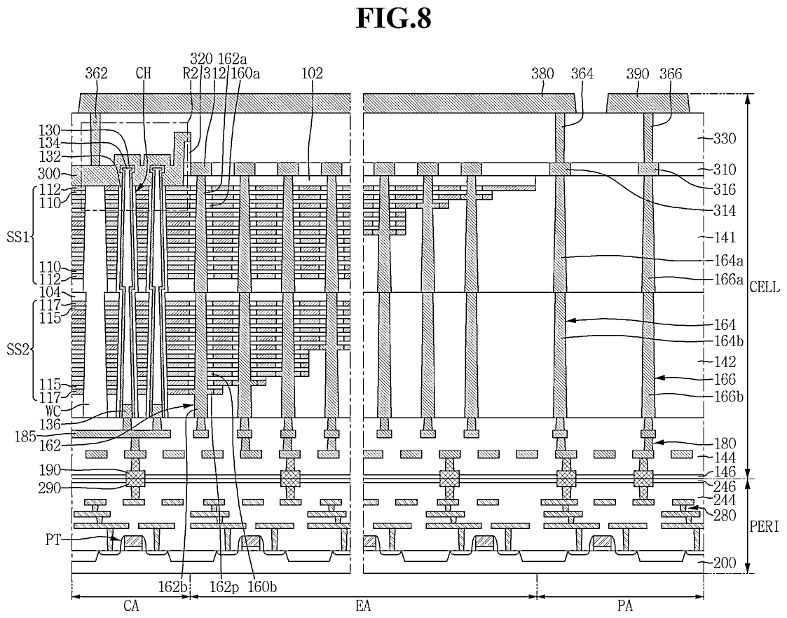

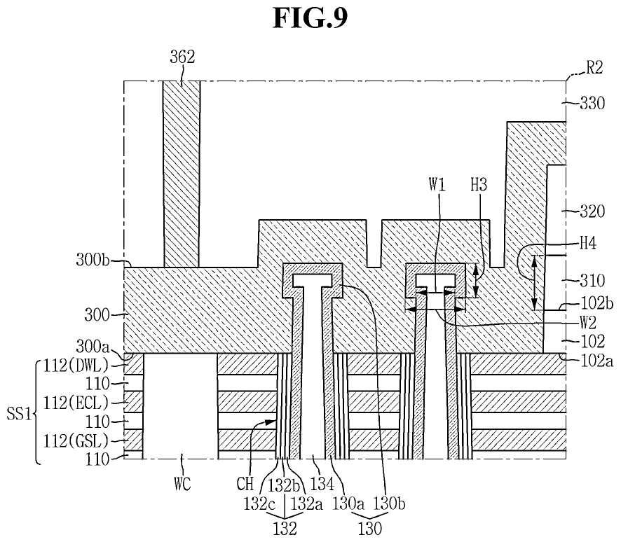

FIG. 8 is a cross-sectional view for illustrating a semiconductor memory device according to some embodiments. FIG. 9 is various enlarged views of a R2 area in FIG. 8. For convenience of description, descriptions similar or identical to those as set forth above using FIGS. 1 to 6D are briefly set forth or omitted.

Referring to FIG. 8 and FIG. 9, in the semiconductor memory device according to some embodiments, the semiconductor film 130 includes a pillar portion 130a and a pad portion 130b.

The pillar portion 130a may extend in the third direction Z and extend through the stack structures SS1 and SS2. The pillar portion 130a may intersect the plurality of gate electrodes 112 and 117. For example, the pillar portion 130a may be a pillar-shaped (e.g., cylindrical) structure extending in the vertical direction (e.g., the third direction Z).

The pad portion 130b may extend from an upper end of the pillar portion 130a. The pad portion 130b may contact the source layer 300. A side portion of the pad portion 130b may extend in a vertical direction (e.g., the third direction Z), and an upper portion of the pad portion 130b may extend along the horizontal plane (e.g., the XY plane).

In some embodiments, a side surface of the pad portion 130b may protrude laterally outwardly beyond a side surface of the pillar portion 130a. For example, at a boundary between the pillar portion 130a and the pad portion 130b, a width W2 of the pad portion 130b may be larger than a width W1 of the pillar portion 130a. In this regard, each of the widths W1 and W2 means a width in the horizontal direction (e.g., the first direction X and/or the second direction Y).

In some embodiments, a height H3 of the pad portion 130b may be smaller than a thickness H4 of the pad insulating film 310. For example, as shown, a vertical level of an upper surface of the pad portion 130b may be lower than a vertical level of the upper surface of the pad insulating film 310, while a vertical level of a lower surface of the pad portion 130b may be higher than a vertical level of the lower surface of the pad insulating film 310, relative to the substrate 200.

In some embodiments, each of the gate contacts 162 may extend through the stack structures SS1 and SS2. For example, a plurality of third contact pads 312 may be formed within the pad insulating film 310 of the extension area EA. The plurality of gate contacts 162 may extend through the stack structures SS1 and SS2 so as to be electrically connected to the corresponding third contact pads 312, respectively. In some embodiments, each gate contact 162 may include a first through-portion 162a, a second through-portion 162b, and a protrusion 162p.

The first through-portion 162a may extend in the third direction Z and may extend through the first base insulating film 102, the first stack structure SS1, and the first interlayer insulating film 141 so as to contact the third contact pad 312. The second through-portion 162b may extend through the second base insulating film 104, the second stack structure SS2, and the second interlayer insulating film 142 so as to contact the first through-portion 162a. The protrusion 162p may protrude from a side surface of the first through-portion 162a or a side surface of the second through-portion 162b so as to contact at least one of the gate electrodes 112 and 117. In some embodiments, the protrusion 162p may contact the lowest gate electrode (hereinafter, a select gate electrode) positioned at the lowest step among the gate electrodes 112 and 117 of the extension area EA, that is, the gate electrode 112 that is closest to the substrate 200.

The gate electrodes (non-select gate electrodes) other than the select gate electrode among the gate electrodes 112 and 117 may be spaced apart from the gate contact 162. For example, a first insulating ring 160a may be formed between the non-select gate electrodes and the first through-portion 162a, and a second insulating ring 160b may be formed between the non-select gate electrodes and the second through-portion 162b. The first insulating ring 160a and the second insulating ring 160b may not be interposed between the gate contact 162 and the select gate electrode.

In some embodiments, the gate contact 162 may have a stepped portion between the first stack structure SS1 and the second stack structure SS2. For example, a width of the first through-portion 162a may decrease as the first through-portion 162a extends toward the third contact pad 312, while a width of the second through-portion 162b may decrease as the second through-portion 162b extends toward the first through-portion 162a. Furthermore, at a boundary or interface between the first interlayer insulating film 141 and the second base insulating film 104, the width of the first through-portion 162a may be larger than the width of the second through-portion 162b to define the step difference or stepped portion.

In some embodiments, the first through-via 164 may have a stepped portion between the first stack structure SS1 and the second stack structure SS2. For example, the first through-via 164 may include a third through-portion 164a and a fourth through-portion 164b. The third through-portion 164a may extend through the first interlayer insulating film 141 and contact the first contact pad 314. The fourth through-portion 164b may extend through the second interlayer insulating film 142 and contact the third through-portion 164a. A width of the third through-portion 164a may decrease as the third through-portion 164a extends toward the first contact pad 314, while a width of the fourth through-portion 164b may decrease as the fourth through-portion 164b extends toward the third through-portion 164a. Furthermore, at a boundary or interface between the first interlayer insulating film 141 and the second interlayer insulating film 142, the width of the third through-portion 164a may be larger than the width of the fourth through-portion 164b to define the step difference or stepped portion.

In some embodiments, the second through-via 166 may have a stepped portion between the first stack structure SS1 and the second stack structure SS2. For example, the second through-via 166 may include a fifth through-portion 166a and a sixth through-portion 166b. The fifth through-portion 166a may extend through the first interlayer insulating film 141 and contact the second contact pad 316. The sixth through-portion 166b may extend through the second interlayer insulating film 142 and contact the fifth through-portion 166a. A width of the fifth through-portion 166a may decrease as it extends toward the second contact pad 316, while a width of the sixth through-portion 166b may decrease as it extends toward the fifth through-portion 166a. Furthermore, at a boundary or interface between the first interlayer insulating film 141 and the second interlayer insulating film 142, the width of the fifth through-portion 166a may be larger than the width of the sixth through-portion 166b to define the step difference or stepped portion.

Hereinafter, with reference to FIGS. 7 to 29, a method for manufacturing a semiconductor memory device according to some embodiments is described.

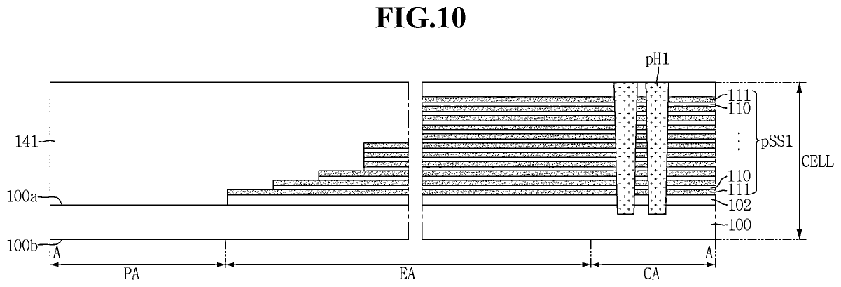

FIGS. 10 to 22 are diagrams of intermediate structures corresponding to intermediate steps of a method for manufacturing a semiconductor memory device according to some embodiments. For convenience of descriptions, descriptions similar or identical to those as set forth above using FIGS. 1 to 6D are briefly set forth or omitted.

Referring to FIG. 10, the first base insulating film 102, a first pre-stack pSS1, and a first pre-channel pH1 are formed on the base substrate 100.

The base substrate 100 may include, for example, a semiconductor substrate such as a silicon substrate, a germanium substrate, or a silicon-germanium substrate. Alternatively, the base substrate 100 may include a silicon-on-insulator (SOI) substrate or a GOI (Germanium-On-Insulator) substrate, etc.

The base substrate 100 may include a fifth surface 100a and a sixth surface 100b that are opposite to each other. In following descriptions, the fifth surface 100a may also be referred to as a front side or surface of the base substrate 100, and the sixth surface 100b may also be referred to as a back side or surface of the base substrate 100.

The first base insulating film 102 and the first pre-stack pSS1 may be sequentially stacked on the fifth surface 100a of the base substrate 100. The first pre-stack pSS1 may include a plurality of first mold insulating films 110 and a plurality of first mold sacrificial films 111 that are alternately stacked on top of each other while being disposed on the first base insulating film 102. The first mold sacrificial films 111 may include a material having an etch selectivity with respect to a material of the first mold insulating films 110. In one example, each of the first mold insulating films 110 may include a silicon oxide film, and each of the first mold sacrificial films 111 may include a silicon nitride film.

The first pre-channel pH1 may extend through the first base insulating film 102 and the first pre-stack pSS1. Furthermore, the first pre-channel pH1 may be in contact with base substrate 100. For example, the first interlayer insulating film 141 covering the first base insulating film 102 and the first pre-stack pSS1 may be formed on the base substrate 100. The first pre-channel pH1 may extend through the first interlayer insulating film 141, the first pre-stack pSS1, and the first base insulating film 102 so as to contact the base substrate 100. In some embodiments, a vertical level of a lower surface of the first pre-channel pH1 may be lower than a vertical level of the fifth surface 100a of the base substrate 100. That is, the first pre-channel pH1 may extend into the base substrate 100 beyond the fifth surface 100a.

The first pre-channel pH1 may include a material having an etch selectivity with respect to a material of each of the first mold insulating films 110 and the first mold sacrificial films 111. In one example, the first pre-channel pH1 may include polysilicon (poly-Si).

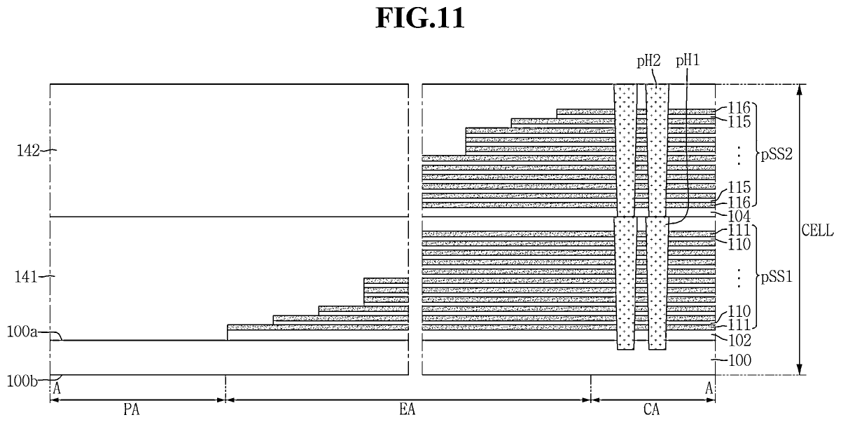

Referring to FIG. 11, the second base insulating film 104, a second pre-stack pSS2, and a second pre-channel pH2 are formed on the first interlayer insulating film 141.

The second base insulating film 104 and the second pre-stack pSS2 may be sequentially stacked on the first interlayer insulating film 141. The second pre-stack pSS2 may include a plurality of second mold insulating films 115 and a plurality of second mold sacrificial films 116 that are alternately stacked on top of each other while being disposed on the second base insulating film 104. Since forming the second pre-stack pSS2 may be similar to forming the first pre-stack pSS1, detailed description thereof is omitted below.

The second pre-channel pH2 may extend through the second base insulating film 104 and the second pre-stack pSS2. Furthermore, the second pre-channel pH2 may be in contact with the first pre-channel pH1. Since forming the second pre-channel pH2 may be similar to forming the first pre-channel pH1, detailed description thereof is omitted below.

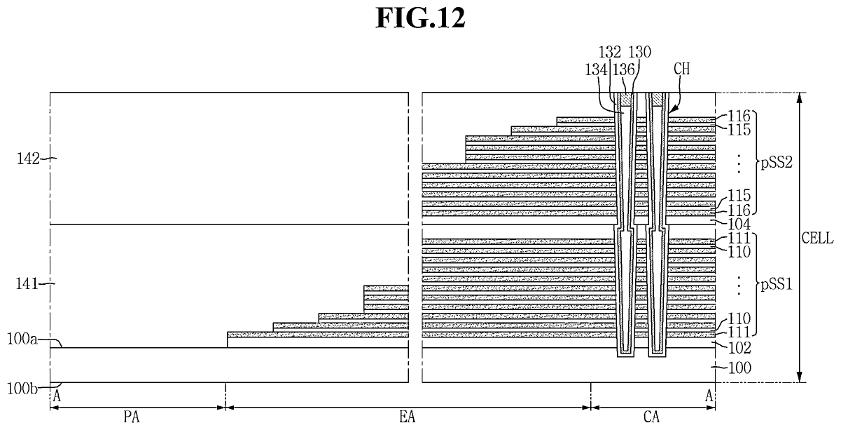

Referring to FIG. 12, the channel structure CH is formed.

For example, the first pre-channel pH1 and the second pre-channel pH2 may be selectively removed. Subsequently, in an area from which the first pre-channel pH1 and the second pre-channel pH2 have been removed, the data storage film 132, the semiconductor film 130, the filling insulating film 134, and the channel pad 136 may be formed in this order. Thus, the channel structure CH that extend throughs the first pre-stack pSS1 and the second pre-stack pSS2 so as to be in contact with the base substrate 100 may be formed.

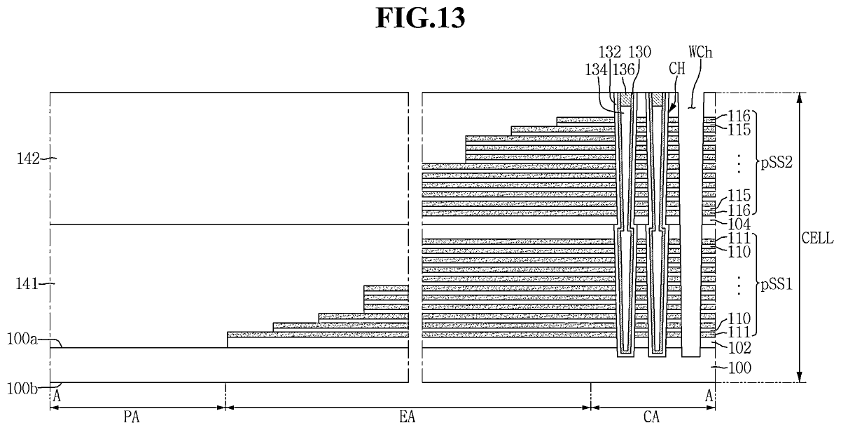

Referring to FIG. 13, a cutting area WCh is formed.

The cutting area WCh may extend in the first direction X so as to cut the first pre-stack pSS1 and the second pre-stack pSS2. In some embodiments, a vertical level of a lower surface of the cutting area WCh may be lower than that of the fifth surface 100a of the base substrate 100. That is, the cutting area WCh may extend into the base substrate 100 beyond the fifth surface 100a.

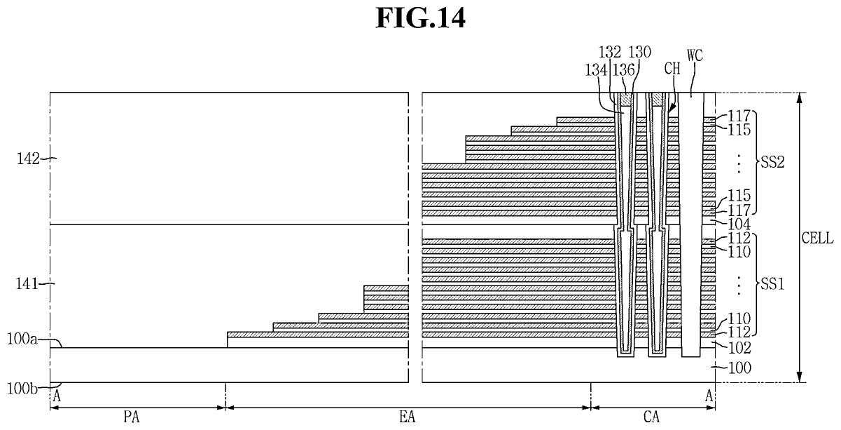

Referring to FIG. 14, the plurality of gate electrodes 112 and 117 are formed.

For example, the mold sacrificial layers 111 and 116 that are exposed through the cutting area WCh may be selectively removed. Subsequently, the gate electrodes 112 and 117 may be formed to fill an area from which the mold sacrificial layers 111 and 116 have been removed. Thus, the stack structures SS1 and SS2 including the mold insulating films 110 and 115 and the gate electrodes 112 and 117 may be formed.

In some embodiments, after the stack structures SS1 and SS2 are formed, the cutting area WCh may be filled with an insulating material. Thus, the cutting pattern WC that cuts the stack structures SS1 and SS2 may be formed.

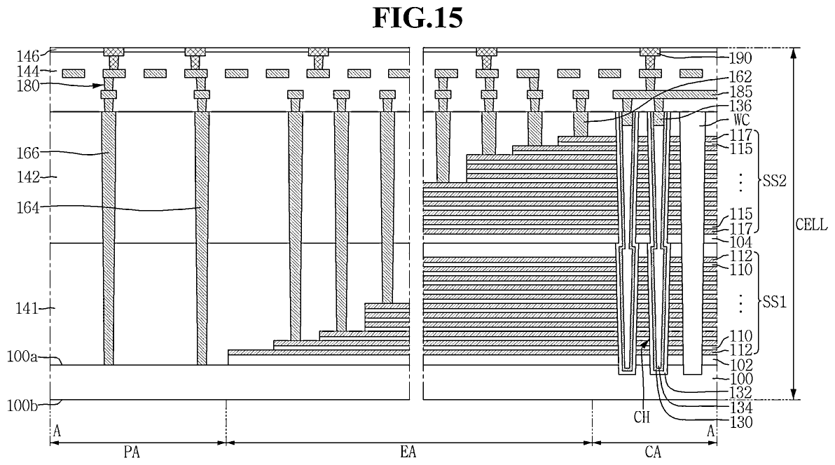

Referring to FIG. 15, the gate contact 162, the first through-via 164, the second through-via 166, the first inter-wiring insulating film 144, the first wiring structure 180, the first bonding insulating film 146, and the first bonding metal 190 are formed.

The gate contact 162 may be disposed within the extension area EA. The plurality of gate contacts 162 may extend through the interlayer insulating films 141 and 142 and contact the corresponding plurality of gate electrodes 112 and 117, respectively.

Each of the first through-via 164 and the second through-via 166 may be disposed within the peripheral area PA. Each of the first through-via 164 and the second through-via 166 may extend through the interlayer insulating films 141 and 142 so as to contact the base substrate 100.

The first inter-wiring insulating film 144 and the first wiring structure 180 may be formed on the second interlayer insulating film 142. The first wiring structure 180 may be electrically connected to the channel structure CH, the gate contact 162, the first through-via 164, and/or the second through-via 166.

The first bonding insulating film 146 and the first bonding metal 190 may be formed on the first inter-wiring insulating film 144. The first bonding metal 190 may be electrically connected to the first wiring structure 180.

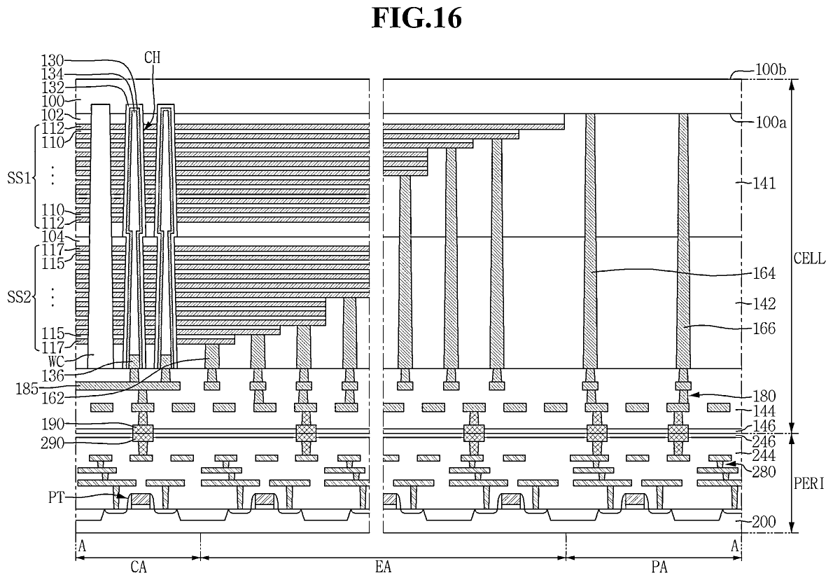

Referring to FIG. 16, the memory cell structure CELL is stacked on the peripheral circuit structure PERI.

In some embodiments, the memory cell structure CELL may be stacked so that the fifth surface 100a of the base substrate 100 faces the peripheral circuit structure PERI. For example, the first bonding metal 190 (and/or the first bonding insulating film 146) as the uppermost metal layer of the memory cell structure CELL and the second bonding metal 290 (and/or the second bonding insulating film 244) as the uppermost metal layer of the peripheral circuit structure PERI may be bonded to each other.

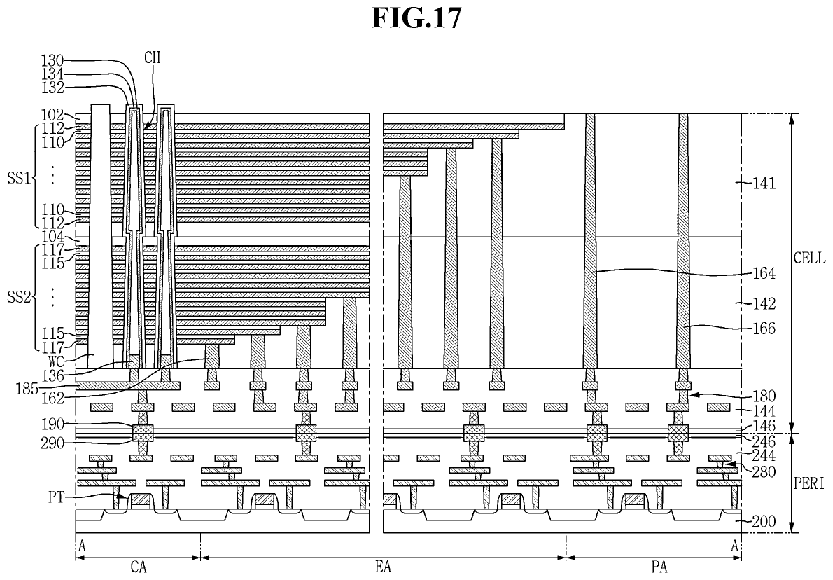

Referring to FIG. 17, at least a portion of the base substrate 100 is removed.

For example, a planarization process and/or a recess process may be performed on the sixth surface 100b of the base substrate 100. One end (for example, an upper end) of the channel structure CH may protrude upwardly beyond the upper surface of the first base insulating film 102.

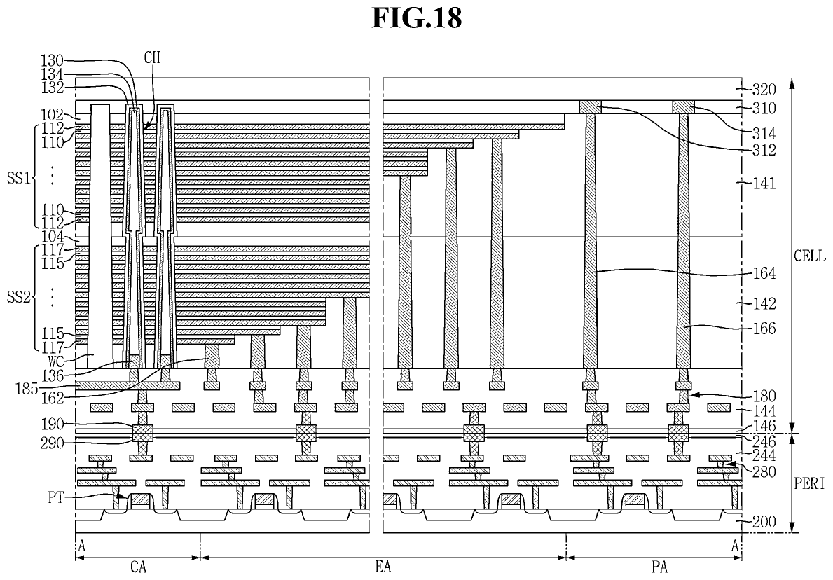

Referring to FIG. 18, the pad insulating film 310, the first contact pad 314, the second contact pad 316, and the first upper insulating film 320 are formed.

The pad insulating film 310 may cover the first base insulating film 102 and the first interlayer insulating film 141 while being disposed to extend across the cell array area CA, extension area EA, and peripheral area PA. The first contact pad 314 and the second contact pad 316 may be formed within the pad insulating film 310. The first contact pad 314 may be in contact with the first through-via 164, and the second contact pad 316 may be in contact with the second through-via 166.

The first upper insulating film 320 may cover the pad insulating film 310, the first contact pad 314, and the second contact pad 316.

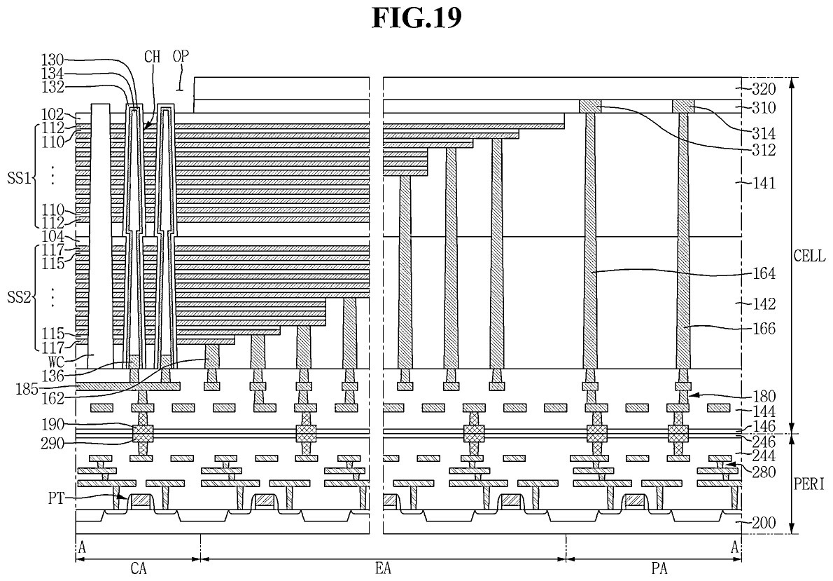

Referring to FIG. 19, the channel structure CH is exposed.

For example, an etching process may be performed on the first upper insulating film 320 and the pad insulating film 310 of the cell array area CA. As the etching process is performed, an opening OP may be formed in the first upper insulating film 320 and the pad insulating film 310 of the cell array area CA. The channel structure CH, the cutting pattern WC, and the first base insulating film 102 of the cell array area CA may be exposed through the opening OP.

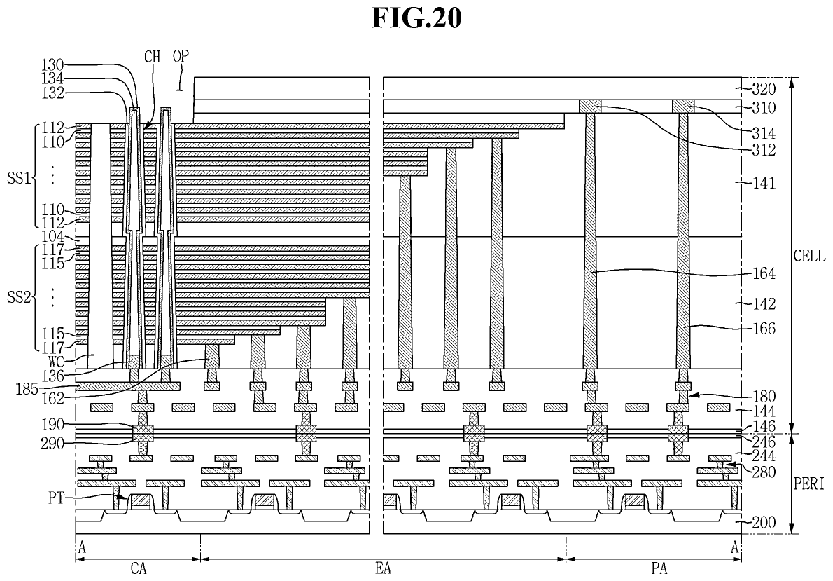

Referring to FIG. 20, an upper portion of the data storage film 132 is removed.

For example, an etching process may be performed on a portion of the data storage film 132 exposed through the opening OP. Thus, one end (e.g., the upper end) of the semiconductor film 130 may be exposed.

In the etching process on the data storage film 132, the first gate electrode 112 (for example, the uppermost gate electrode 112u in FIG. 6A) disposed at a top level among the plurality of first gate electrodes 112 may act as an etch stop film. For example, the etching process on the data storage film 132 may be performed until the first gate electrode 112 disposed at the top level is exposed from the first base insulating film 102. In the etching process on the data storage film 132, the first gate electrode 112 disposed at the top level may protect underlying other gate electrodes (e.g., the erase control line ECL, the ground select line GSL, and/or the word-line WL).

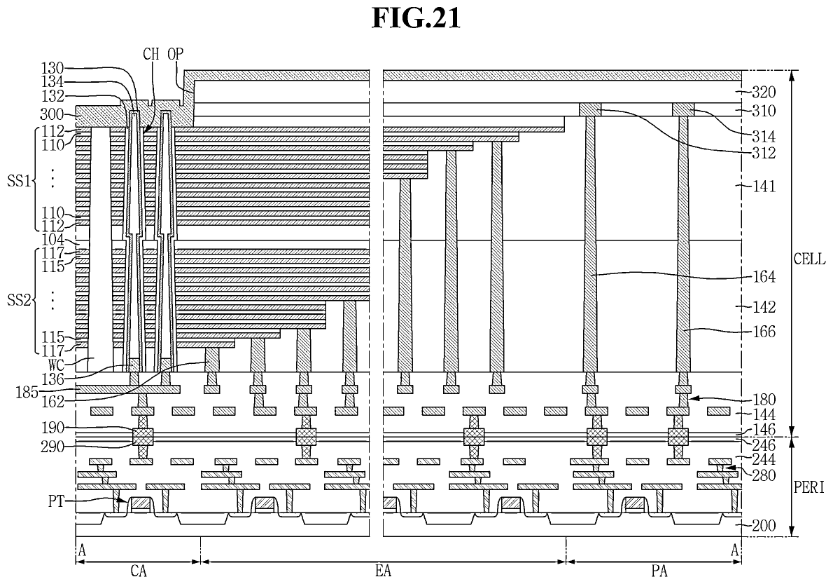

Referring to FIG. 21, the source layer 300 is formed within the opening OP.

For example, the source layer 300 may cover the first stack structure SS1 and the first upper insulating film 320. Thus, the source layer 300 may be in contact with the exposed one end (e.g., the upper end) of the semiconductor film 130. Furthermore, the source layer 300 may contact the first gate electrode 112 (for example, the uppermost gate electrode 112u in FIG. 6A) disposed at the top level among the plurality of first gate electrodes 112.

The source layer 300 may include a conductive material, for example, polysilicon doped with impurities, metal, or metal silicide. However, embodiments of the present disclosure are not limited thereto. In one example, the source layer 300 may include poly-silicon (poly-Si) doped with N-type impurities (e.g., phosphorus (P) or arsenic (As)).

In some embodiments, after forming the source layer 300, a laser annealing process may be performed on the source layer 300. As the laser annealing process is performed, crystallization of the source layer 300 may be induced or the impurities contained in the source layer 300 may be activated. In the laser annealing process, the first gate electrode 112 disposed at the top level may protect the underlying other gate electrodes (e.g., the erase control line ECL, the ground select line GSL, and/or the word-line WL).

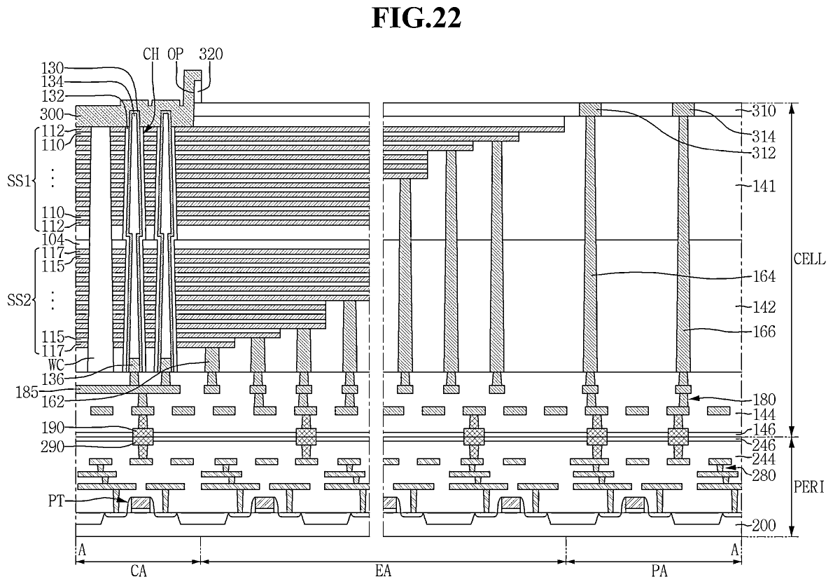

Referring to FIG. 22, the source layer 300 of or extending onto the extension area EA and/or the peripheral area PA is removed.

For example, an etching process may be performed on the source layer 300 and the first upper insulating film 320 in the extension area EA and the peripheral area PA.

Subsequently, referring to FIG. 5, the second upper insulating film 330, the first contact pattern 362, the second contact pattern 364, the third contact pattern 366, the connection pattern 380, and the conductive pad 390 may be formed.

Thus, the semiconductor memory device as described above using FIG. 5 may be manufactured.

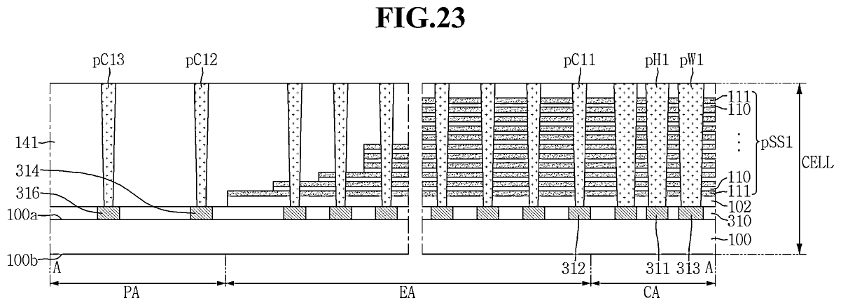

FIGS. 23 to 28 are diagrams of intermediate structures corresponding to intermediate steps of a method for manufacturing a semiconductor memory device according to some embodiments. For convenience of descriptions, descriptions similar or identical to those as set forth above using FIGS. 1 to 22 are briefly set forth or omitted.

Referring to FIG. 23, the pad insulating film 310, the first contact pad 314, the second contact pad 316, the third contact pad 312, a first sacrificial pad 311, a second sacrificial pad 313, the first base insulating film 102, the first pre-stack pSS1, the first pre-channel pH1, a first pre-cutting pattern pW1, a first pre-gate contact pC11, a first pre-through-via pC12, and a second pre-through-via pC13 are formed on the base substrate 100.

The pad insulating film 310 may be formed on the fifth surface 100a of the base substrate 100. The first contact pad 314, the second contact pad 316, the third contact pad 312, the first sacrificial pad 311, and the second sacrificial pad 313 may be formed within the pad insulating film 310. The first base insulating film 102 and the first pre-stack pSS1 may be sequentially stacked on the upper surface of the pad insulating film 310. The first interlayer insulating film 141 may cover the pad insulating film 310, the first base insulating film 102, and the first pre-stack pSS1.

Each of the first pre-channel pH1, the first pre-cutting pattern pW1, the first pre-gate contact pC11, the first pre-through-via pC12, and the second pre-through-via pC13 may extend through the first base insulating film 102, the pre-stack pSS1 and the first interlayer insulating film 141. The first pre-channel pH1 may be in contact with the first sacrificial pad 311. The first pre-cutting pattern pW1 may be in contact with the second sacrificial pad 313. The first pre-gate contact pC11 may be in contact with the third contact pad 312. The first pre-through-via pC12 may be in contact with the first contact pad 314. The second pre-through-via pC13 may be in contact with the second contact pad 316.

Each of the first pre-channel pH1, the first pre-cutting pattern pW1, the first pre-gate contact pC11, the first pre-through-via pC12, and the second pre-through-via pC13 may include a material having an etch selectivity with respect to a material of each of the first mold insulating films 110 and the first mold sacrificial layers 111.

In some embodiments, the first pre-channel pH1, the first pre-cutting pattern pW1, the first pre-gate contact pC11, the first pre-through-via pC12, and the second pre-through-via pC13 may be disposed at the same vertical level as each other and thus may be formed simultaneously. As used herein, “the same vertical level” means being formed in the same manufacturing process and/or with a same height (e.g., relative to an underlying substrate, such as the substrate 100).

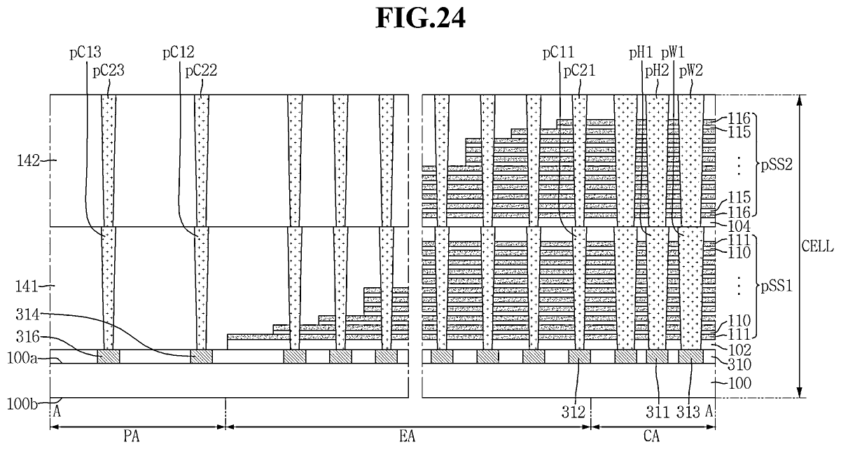

Referring to FIG. 24, the second base insulating film 104, the second pre-stack pSS2, the second pre-channel pH2, a second pre-cutting pattern pW2, a second pre-gate contact pC21, a third pre-through-via pC22 and a fourth pre-through-via pC23 are formed on the first interlayer insulating film 141.

The second base insulating film 104 and the second pre-stack pSS2 may be sequentially stacked on the first interlayer insulating film 141. The second interlayer insulating film 142 may cover the second base insulating film 104 and the second pre-stack pSS2.

Each of the second pre-channel pH2, the second pre-cutting pattern pW2, the second pre-gate contact pC21, the third pre-through-via pC22, and the fourth pre-through-via pC23 may extend through the second base insulating film 104, the second pre-stack pSS2 and the second interlayer insulating film 142. The second pre-channel pH2 may be in contact with the first pre-channel pH1. The second pre-cutting pattern pW2 may be in contact with the first pre-cutting pattern pW1. The second pre-gate contact pC21 may be in contact with the first pre-gate contact pC11. The third pre-through-via pC22 may be in contact with the first pre-through-via pC12. The fourth pre-through-via pC23 may be contacted with the second pre-through-via pC13.

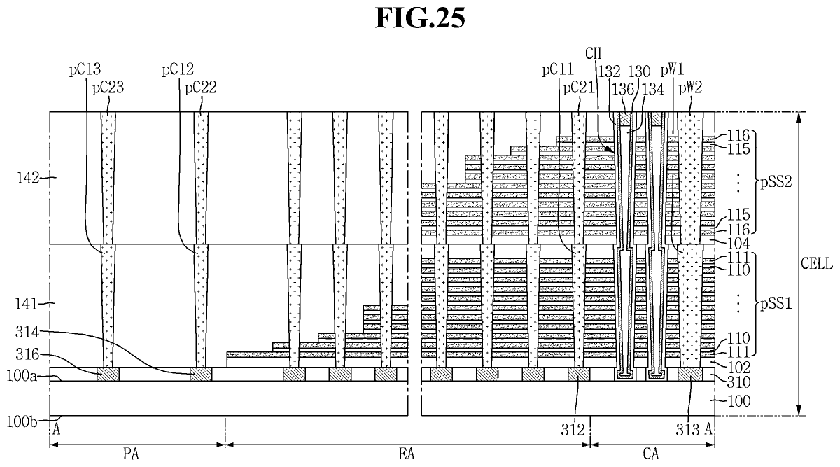

Referring to FIG. 25, the channel structure CH is formed.

For example, the first sacrificial pad 311, the first pre-channel pH1, and the second pre-channel pH2 may be selectively removed. Subsequently, in an area where the first sacrificial pad 311, the first pre-channel pH1, and the second pre-channel pH2 have been removed, the data storage film 132, the semiconductor film 130, the filling insulating film 134, and the channel pad 136 may be formed in this order. Thus, the channel structure CH that extends through the pad insulating film 310, the first pre-stack pSS1, and the second pre-stack pSS2 so as to be in contact with the base substrate 100 may be formed.

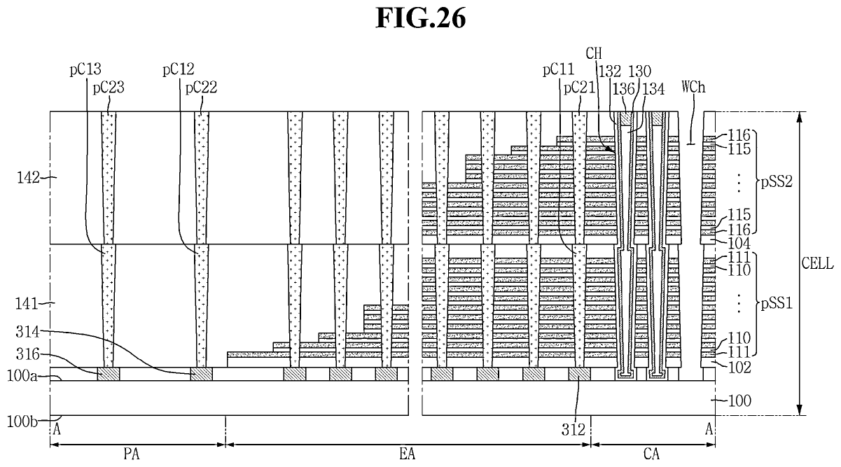

Referring to FIG. 26, the cutting area WCh is formed.

For example, the second sacrificial pad 313, the first pre-cutting pattern pW1, and the second pre-cutting pattern pW2 may be selectively removed. The cutting area WCh may extend in the first direction X to cut the pad insulating film 310, the first pre-stack pSS1, and the second pre-stack pSS2.

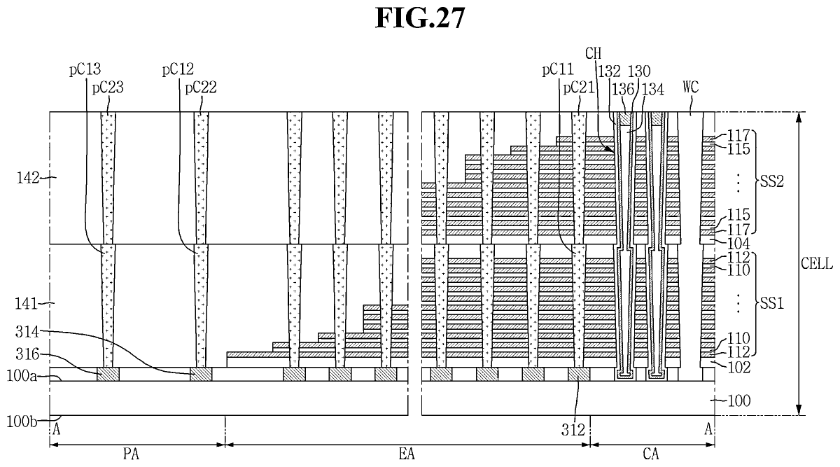

Referring to FIG. 27, the plurality of gate electrodes 112 and 117 are formed, and the cutting area WCh is be filled with an insulating material to form the cutting pattern WC.

Forming the plurality of gate electrodes 112 and 117 is similar to what has been described above using FIG. 14. Thus, detailed description thereof is omitted below.

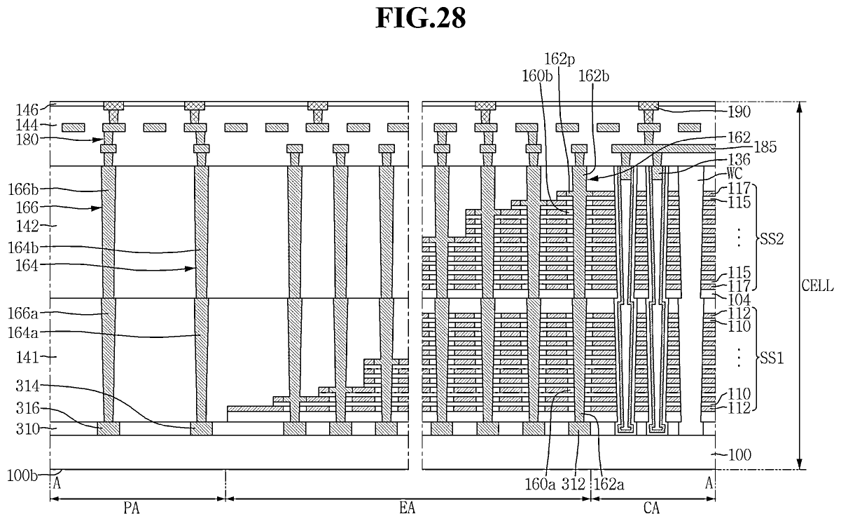

Referring to FIG. 28, the gate contact 162, the first through-via 164, and the second through-via 166 are formed.

For example, the first pre-gate contact pC11 and the second pre-gate contact pC21 may be selectively removed. Subsequently, the gate contact 162 may be formed to fill an area from which the first pre-gate contact pC11 and the second pre-gate contact pC21 have been removed.

Furthermore, for example, the first pre-through-via pC12, the second pre-through-via pC13, the third pre-through-via pC22, and the fourth pre-through-via pC23 may be selectively removed. Subsequently, the first through-via 164 and the second through-via 166 may be formed to fill an area from which the first pre-through-via pC12, the second pre-through-via pC13, the third pre-through-via pC22, and the fourth pre-through-via pC23 have been removed.

Subsequently, the steps as described above using FIGS. 15 to 22 may be performed. Subsequently, referring to FIG. 8, the second upper insulating film 330, the first contact pattern 362, the second contact pattern 364, the third contact pattern 366, the connection pattern 380, and the conductive pad 390 may be formed. Thus, the semiconductor memory device as described above using FIG. 8 may be manufactured.

Hereinafter, referring to FIG. 1 to FIG. 31, an electronic system including the semiconductor memory device according to some embodiments is described.

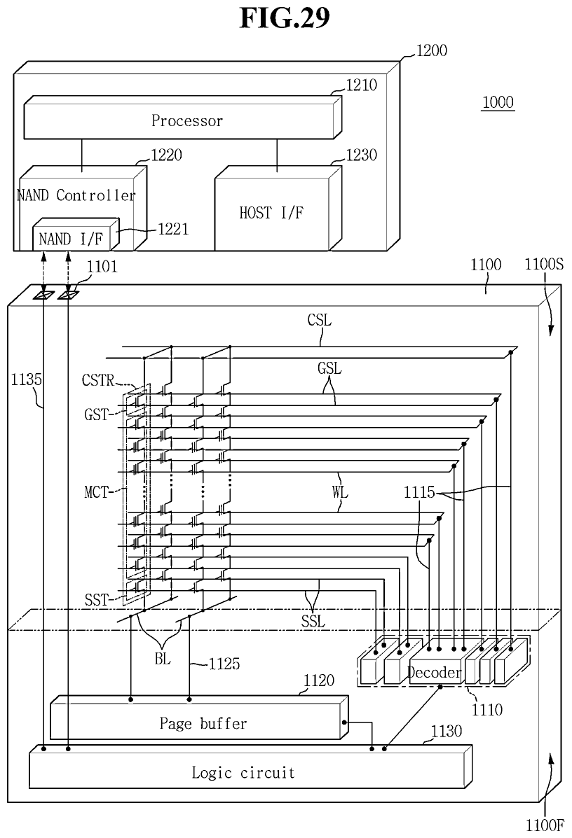

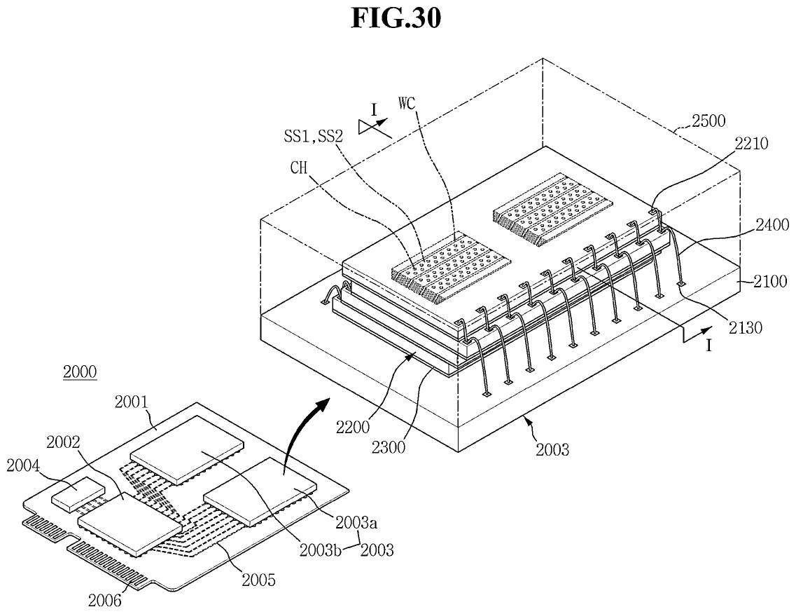

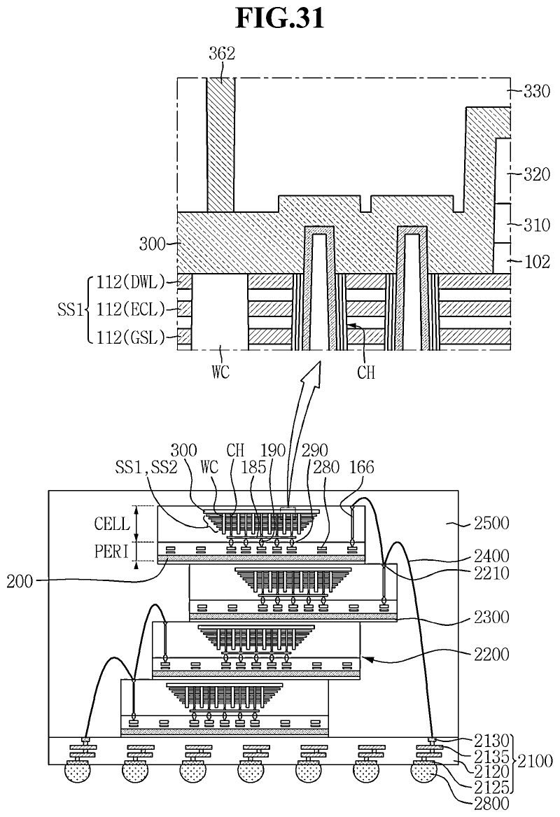

FIG. 29 is an illustrative block diagram for illustrating an electronic system according to some embodiments. FIG. 30 is an illustrative perspective view for illustrating an electronic system according to some embodiments. FIG. 31 is a schematic cross-sectional view taken along I-I of FIG. 30. For convenience of descriptions, descriptions similar or identical to those as set forth above using FIGS. 1 to 28 are briefly set forth or omitted.

Referring to FIG. 29, an electronic system 1000 according to some embodiments may include a semiconductor memory device 1100 and a controller 1200 electrically connected to the semiconductor memory device 1100. The electronic system 1000 may be a storage device storage device including one or a plurality of semiconductor devices 1100 or an electronic device electronic device including the storage device. For example, the electronic system 1000 may be embodied as a solid state drive device (SSD), a Universal Serial Bus (USB), a computing system, a medical device, or a communication device including one or a plurality of semiconductor memory devices 1100.

The semiconductor memory device 1100 may be embodied as a non-volatile memory device (e.g., a NAND flash memory device). The semiconductor memory device 1100 may be embodied, as for example, at least one of the semiconductor devices as described above with reference to FIGS. 1 to 9. The semiconductor memory device 1100 may include a first structure 1100F and a second structure 1100S on the first structure 1100F.

The first structure 1100F may be a peripheral circuit structure including a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1). The first structure 1100F may be embodied as, for example, the peripheral circuit structure PERI as described above with reference to FIGS. 1 to 9.

The second structure 1100S may include the common source line CSL, the plurality of bit-lines BL and the plurality of cell strings CSTR as above-described with reference to FIG. 2. The cell strings CSTR may be connected to the decoder circuit 1110 via the plurality of word-lines WL, at least one string select line SSL, and at least one ground select line GSL. Further, the cell strings CSTR may be connected to the page buffer 1120 via the bit-lines BL. The second structure 1100S may be embodied as, for example, the memory cell structure CELL as described above using FIGS. 1 to 9.

In some embodiments, the common source line CSL and the cell string CSTR may be electrically connected to the decoder circuit 1110 via a first connection wiring 1115 extending from the first structure 1100F to the second structure 1100S. The first connection wirings 1115 may be embodied as, for example, the gate contacts 162 and/or the first through-via 164 as described above using FIGS. 1 to 9.

In some embodiments, the bit-lines BL may be electrically connected to the page buffer 1120 via a second connection wiring 1125.

The semiconductor memory device 1100 may communicate with the controller 1200 via an input/output pad 1101 electrically connected to the logic circuit 1130 (e.g., the control logic 37 in FIG. 1). For example, the input/output pad 1101 may correspond to the conductive pad 390 as described above using FIGS. 1 to 9. The input/output pad 1101 may be electrically connected to the logic circuit 1130 via an input/output connection line 1135 extending from the first structure 1100F to the second structure 1100S. The connection line 1135 may be embodied as, for example, the second through-via 166 as described with reference to FIGS. 1 to 9.

The controller 1200 may include a processor 1210, a NAND controller 1220, and a host interface 1230. In some embodiments, the electronic system 1000 may include a plurality of semiconductor memory devices 1100. In this case, the controller 1200 may control the plurality of semiconductor memory devices 1100.

The processor 1210 may control overall operations of the electronic system 1000 including the controller 1200. The processor 1210 may operate based on predefined firmware, and may control the NAND controller 1220 to access the semiconductor memory device 1100. The NAND controller 1220 may include a NAND interface 1221 that processes communication with the semiconductor memory device 1100. Via the NAND interface 1221, a control command for controlling the semiconductor memory device 1100, data to be written to memory cell transistors MCT of the semiconductor memory device 1100, and data to be read from the memory cell transistors MCT of the semiconductor memory device 1100 may be transmitted. The host interface 1230 may provide a communication function between the electronic system 1000 and an external host. Upon receiving a control command from an external host via the host interface 1230, the processor 1210 may control the semiconductor memory device 1100 in response to the control command.

Referring to FIG. 30 and FIG. 31, an electronic system according to some embodiments may include a main substrate 2001, a main controller 2002 mounted on the main substrate 2001, at least one semiconductor package 2003, and at least one DRAM 2004. The semiconductor package 2003 and the DRAM 2004 may be connected to the main controller 2002 via line patterns 2005 formed on the main substrate 2001.

The main substrate 2001 may include a connector 2006 including a plurality of pins configured to be coupled to an external host. The number and an arrangement of the plurality of pins in the connector 2006 may vary based on a communication interface between the electronic system 2000 and the external host. In some embodiments, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. In some embodiments, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart (e.g., laterally) from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a bottom face of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may be embodied as the input/output pad 1101 in FIG. 29.

In some embodiments, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some embodiments, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In some embodiments, the main controller 2002 and the semiconductor chips 2200 may be included in one package. In some embodiments, the main controller 2002 and the semiconductor chips 2200 may be mounted on a separate interposer substrate different from the main substrate 2001, and the main controller 2002 and the semiconductor chips 2200 may be connected to each other via a line formed in the interposer substrate.

In some embodiments, the package substrate 2100 may be embodied as a printed circuit board. The package substrate 2100 may include a package substrate body 2120, the package upper pads disposed on a upper face of the package substrate body 2120, package lower pads 2125 disposed on a bottom face of the package substrate body 2120, or exposed through the bottom face thereof, and internal lines 2135 disposed in the package substrate body 2120 so as to electrically connect the upper pads 2130 and the lower pads 2125 to each other. The upper pads 2130 may be electrically connected to the connection structures 2400. The lower pads 2125 may be connected to the line patterns 2005 of the main substrate 2010 of the electronic system 2000 via conductive connectors 2800 as shown in FIG. 31.

In the electronic system 2000 according to some embodiments, each of the semiconductor chips 2200 may include the semiconductor memory device as described above using FIGS. 1 to 9. For example, each of the semiconductor chips 2200 may include the memory cell structure CELL and the peripheral circuit structure PERI. By way of example, the memory cell structure CELL may include the first stack structure SS1, the second stack structure SS2, the channel structure CH, the cutting pattern WC, the second through-via 166, the first wiring structure 180 and the source layer 300 as described above using FIGS. 1 to 9. The peripheral circuit structure PERI may include the peripheral circuit substrate 200 and the second wiring structure 280. The memory cell structure CELL and the peripheral circuit structure PERI may be bonded to each other via the first bonding metal 190 and the second bonding metal 290.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical scope or essential characteristics of the present disclosure. Therefore, it should be appreciated that the embodiments as described above is not restrictive but illustrative in all respects.

What is claimed is:

1. A semiconductor memory device comprising:
a peripheral circuit structure comprising a peripheral circuit substrate and a peripheral circuit element on the peripheral circuit substrate;
a source layer comprising a first surface facing the peripheral circuit structure and a second surface opposite to the first surface;
a stack structure comprising a plurality of mold insulating films and a plurality of gate electrodes alternately stacked on the first surface of the source layer; and
a channel structure extending through the stack structure and contacting the source layer,
wherein the source layer is in contact with an uppermost gate electrode that is closest to the source layer among the plurality of gate electrodes.

2. The semiconductor memory device of claim 1, wherein the uppermost gate electrode is a dummy line,
wherein the plurality of gate electrodes further comprise at least one ground select line, a plurality of word-lines, and at least one string select line sequentially stacked on the dummy line opposite the source layer.

3. The semiconductor memory device of claim 1, wherein the channel structure comprises:
a semiconductor film intersecting the plurality of gate electrodes; and
a data storage film between the semiconductor film and the plurality of gate electrodes,
wherein the semiconductor film protrudes beyond the stack structure and the data storage film and contacts the source layer.

4. The semiconductor film of claim 3, wherein the semiconductor film comprises:
a through-portion extending in a vertical direction and intersecting the plurality of gate electrodes; and
a contact portion extending from the through-portion and contacting the source layer,
wherein a horizontal direction intersects the vertical direction, wherein a width in the horizontal direction of the contact portion is greater than a width in the horizontal direction of the through-portion.

5. The semiconductor memory device of claim 3, wherein the data storage film exposes at least a portion of a side surface of the uppermost gate electrode.

6. The semiconductor memory device of claim 1, further comprising:
a cutting pattern extending in a first direction thorough the stack structure; and
a bit-line between the peripheral circuit structure and the stack structure, and extending in a second direction intersecting the first direction, wherein the bit-line is electrically connected to the channel structure.

7. The semiconductor memory device of claim 6, wherein the cutting pattern exposes at least a portion of a side surface of the uppermost gate electrode.

8. The semiconductor memory device of claim 1, further comprising:
a conductive plate on the second surface of the source layer and in contact with the source layer.

9. The semiconductor memory device of claim 1, wherein the source layer comprises a polysilicon (poly-Si) film doped with impurities.

10. The semiconductor memory device of claim 1, wherein each of the gate electrodes comprises a metal film.

11. A semiconductor memory device comprising:
a peripheral circuit structure comprising a peripheral circuit substrate and a peripheral circuit element on the peripheral circuit substrate;
a memory cell structure stacked on the peripheral circuit structure and comprising a cell array area and an extension area adjacent the cell array area,
wherein the memory cell structure comprises:
an insulating film in the extension area, and including a first surface facing the peripheral circuit structure and a second surface opposite to the first surface;
a source layer in the cell array area, and comprising a third surface facing the peripheral circuit structure and a fourth surface opposite to the third surface;
a stack structure comprising a plurality of mold insulating films and a plurality of gate electrodes alternately stacked on the first surface and the third surface; and
a channel structure comprising:
a semiconductor film extending in a vertical direction intersecting the plurality of gate electrodes; and
a data storage film between the semiconductor film and the plurality of gate electrodes,
wherein the semiconductor film protrudes beyond the stack structure and the data storage film and contacts the source layer,
wherein an uppermost gate electrode that is closest to the source layer among the plurality of gate electrodes is in contact with the first surface and the third surface.

12. The semiconductor memory device of claim 11, wherein the uppermost gate electrode is a dummy line,
wherein the plurality of gate electrodes further comprise at least one erase control line, at least one ground select line, a plurality of word-lines, and at least one string select line sequentially stacked on the dummy line opposite the source layer.

13. The semiconductor memory device of claim 11, wherein a distance by which the semiconductor film protrudes beyond the stack structure is greater than a thickness of the insulating film in the vertical direction.

14. The semiconductor memory device of claim 11, wherein a portion of the insulating film is between the source layer and the stack structure.

15. The semiconductor memory device of claim 11, wherein the plurality of gate electrodes in the extension area are on the first surface and are stacked to define a stepped structure.

16. The semiconductor memory device of claim 11, further comprising:
a source contact on a side surface of the stack structure and extending in the vertical direction, wherein the source contact electrically connects the peripheral circuit element and the source layer.

17. The semiconductor memory device of claim 11, wherein the source layer comprises a poly-silicon (poly-Si) film doped with impurities, and wherein each of the gate electrodes comprises a metal film.

18. An electronic system comprising:
a main substrate;
a semiconductor memory device comprising a peripheral circuit structure and a memory cell structure sequentially stacked on the main substrate; and
a controller on the main substrate and electrically connected to the semiconductor memory device,
wherein the memory cell structure comprises:
a source layer comprising a first surface facing the peripheral circuit structure and a second surface opposite to the first surface;
a stack structure on the first surface of the source layer and including a plurality of gate electrodes sequentially stacked and spaced apart from each other; and
a channel structure intersecting the plurality of gate electrodes and in contact with the source layer,
wherein the source layer is in contact with an uppermost gate electrode that is closest to the source layer among the plurality of gate electrodes.

19. The electronic system of claim 18, wherein the peripheral circuit structure further comprises:
a decoder circuit electrically connected to the plurality of gate electrodes,
wherein the uppermost gate electrode is a dummy line that is not configured to receive a gate voltage from the decoder circuit.

20. The electronic system of claim 19, wherein the plurality of gate electrodes comprises at least one ground select line, a plurality of word-lines, and at least one string select line sequentially stacked on the dummy line opposite the source layer.
